(19) United States
(12) Patent Application Publication
(10) Pub. No.: US 2025/0070678 A1
(43) Pub. Date: Feb. 27, 2025

(54) ISOLATED POWER SUPPLY DEVICE

(71) Applicant: DENSO CORPORATION, Kariya-city (JP)

(72) Inventors: Atsuki ASANO, Kariya-city (JP); Yoshinori HAYASHI, Kariya-city (JP)

(73) Assignee: DENSO CORPORATION, Kariya-city (JP)

(21) Appl. No.: 18/944,353

(22) Filed: Nov. 12, 2024

Related U.S. Application Data
(63) Continuation of application No. PCT/JP2023/014757, filed on Apr. 11, 2023.

(30) Foreign Application Priority Data
May 11, 2022 (JP) 2022-078072

(51) Int. Cl. H02M 3/335

(52) U.S. Cl. CPC H02M 3/33569

(57) ABSTRACT

An isolated power supply device includes a plurality of transformers having input windings and cores. The input windings are connected to a DC power supply. Output sides of the transformers are connected to power feeding targets. At least two of the transformers have control windings. The isolated power supply device includes a control switch, control wirings, and a common wiring. First terminals of the control windings are connected to the ground. Second terminals of the control windings are connected to first terminals of the corresponding control wirings. Second terminals of the control wirings are connected to the common wiring. The isolated power supply device further includes a control unit that turns on and off the control switch based on a voltage value of the common wiring.

### CROSS-REFERENCE TO RELATED APPLICATION

The present application is based on and claims the benefit of priority from earlier Japanese Patent Application No. 2022-078072 filed on May 11, 2022, the description of which is incorporated herein by reference.

### BACKGROUND

### Technical Field

The present disclosure relates to an isolated power supply device.

### Related Art

As an isolated power supply device, a device is known which supplies electrical power from a DC power supply to a plurality of power feeding targets while electrically isolating a DC power supply and the power feeding targets from each other by transformers.

### SUMMARY

An aspect of the present disclosure provides an isolated power supply device, including:

a plurality of transformers having input windings and cores around which the input windings are wound, the input windings being connected to a DC power supply, output sides of the transformers being connected to power feeding targets corresponding to the transformers, at least two of the transformers having control windings magnetically coupled with the input windings via the cores;
a control switch that performs power feeding from the DC power supply to the input windings when being turned on and stops the power feeding from the DC power supply to the input windings when being turned off;
control wirings provided corresponding to the control windings; and
a common wiring, wherein
first terminals of the control windings are connected to the ground,
second terminals of the control windings are connected to first terminals of the corresponding control wirings,
second terminals of the control wirings are connected to the common wiring, and
the isolated power supply device further includes a control unit that turns on and off the control switch based on a voltage value of the common wiring.

### BRIEF DESCRIPTION OF THE DRAWINGS

In the accompanying drawings:

FIG. 1 is a diagram illustrating an overall configuration of a motor control system according to a first embodiment;

FIG. 2 is a diagram illustrating an isolated power supply device;

FIG. 3 is a diagram illustrating an isolated power supply device according to a modification of the first embodiment;

FIG. 4 is a diagram illustrating an isolated power supply device according to a modification of the first embodiment;

FIG. 5 is a diagram illustrating an isolated power supply device according to a modification of the first embodiment;

FIG. 6 is a diagram illustrating an isolated power supply device according to a modification of the first embodiment;

FIG. 7 is a diagram illustrating an isolated power supply device according to a modification of the first embodiment;

FIG. 8 is a diagram illustrating an isolated power supply device according to a modification of the first embodiment;

FIG. 9 is a diagram illustrating an isolated power supply device according to a second embodiment; and

FIG. 10 is a diagram illustrating an isolated power supply device according to a modification of the second embodiment.

### DETAILED DESCRIPTION OF THE PREFERRED EMBODIMENTS

As an isolated power supply device, a device is known which supplies electrical power from a DC power supply to a plurality of power feeding targets while electrically isolating a DC power supply and the power feeding targets from each other by transformers. For example, Japanese Patent No. 6817298 discloses an isolated power supply device that includes a plurality of transformers and a control switch that controls currents flowing to input windings corresponding to the transformers.

The input windings are connected to the DC power supply, and the output sides of the transformers are connected to the power feeding targets corresponding to the transformers. When the control switch is turned on, power is fed from the DC power supply to the input windings. Hence, magnetic energy is stored in the transformers. In contrast, when the control switch is turned off, power feed from the DC power supply to the input windings is stopped. During this, electrical power is supplied from the transformers to the power feeding targets corresponding to the output sides of the transformers.

If variation occurs in the magnitudes of loads of the power feeding targets, there is a concern that controllability of output voltages of the transformers decreases.

Specifically, if variation occurs in the magnitudes of loads of the power feeding targets, in the transformer corresponding to the power feeding target whose load has a small magnitude, due to excessive supply of magnetic energy, output voltage is likely to increase compared with the transformer corresponding to the power feeding target whose load has a large magnitude. In contrast, in the transformer corresponding to the power feeding target whose load has a large magnitude, due to insufficient supply of magnetic energy, output voltage is likely to decrease compared with the transformer corresponding to the power feeding target whose load has a small magnitude. That is, in a state in which variation occurs in the magnitudes of loads of the power feeding targets, variation is likely to occur in output voltages of the transformers

Herein, it can be considered that the control switch may be turned on and off based on an output voltage of any one of the transformers. In this case, in a transformer to be controlled out of the transformers, the control switch is turned on and off so that an output voltage reaches a target output voltage. In contrast, in a transformer not to be controlled out of the transformers, an output voltage basically varies by the difference between the output voltage of the transformer to be controlled and the target output voltage. Hence, if variation occurs in output voltages of the transformers, there is a concern that controllability of output voltages decreases, for example, output voltages of transformers not to be controlled out of the transformers excessively increase or decrease with respect to the target output voltage.

In view of the above points, the present disclosure has an object of providing an isolated power supply device that can increase controllability of output voltages of transformers.

### First Embodiment

Hereinafter, the first embodiment of an isolated power supply device according to the present disclosure will be described with reference to the drawings. The isolated power supply device of the present embodiment is installed in, for example, an electric vehicle including a motor generator but not including an engine.

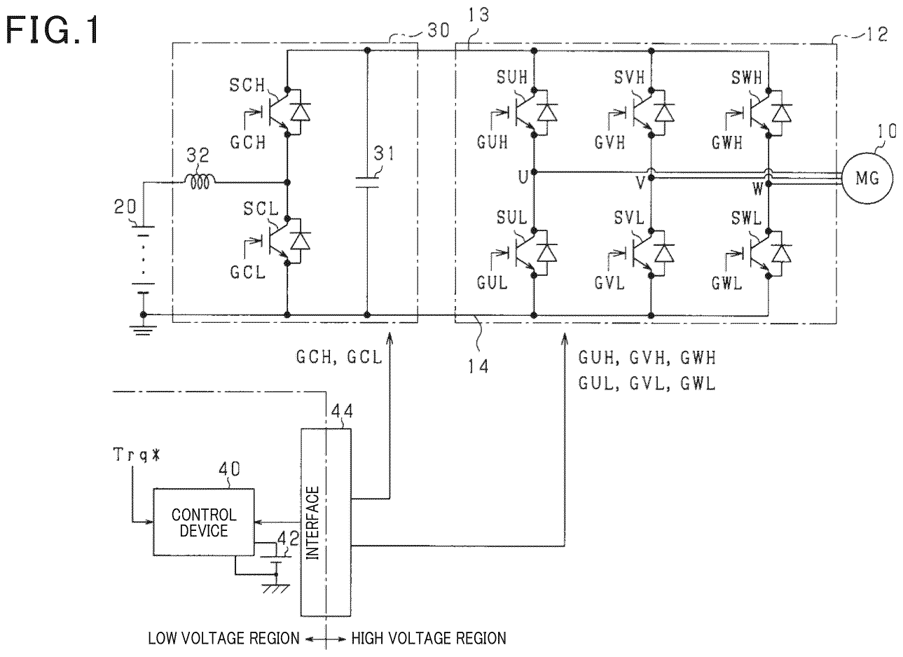

As illustrated in FIG. 1, a motor control system includes a motor generator 10, an inverter 12, a boost converter 30, and a control device 40. The motor generator 10 is coupled with drive wheels via a power dividing mechanism, not shown. The motor generator 10 is connected to the inverter 12 and serves as an in-vehicle traction unit and the like. The inverter 12 is a three-phase inverter and is connected to a high-voltage battery 20 (e.g., a lithium-ion secondary battery or a nickel-hydrogen secondary battery) via the boost converter 30.

The boost converter 30 includes a smoothing capacitor 31, a reactor 32, an upper arm boost switch SCH, and a lower arm boost switch SCL. In the present embodiment, as the upper arm switch SCH and the lower arm switch SCL, a voltage controlled semiconductor switch, specifically, an IGBT is used. The switches SCH, SCL are connected with free-wheel diodes in parallel.

The emitter of the upper arm boost switch SCH is connected to the collector of the lower arm boost switch SCL. The collector of the upper arm boost switch SCH is connected with a first terminal of the smoothing capacitor 31, and the emitter of the lower arm boost switch SCL is connected with a second terminal of the smoothing capacitor 31 and a negative electrode terminal of the high-voltage battery 20. That is, a series connection of the boost switches SCH, SCL is connected with the smoothing capacitor 31 in parallel. The emitter of the upper arm boost switch SCH and the collector of the lower arm boost switch SCL are connected to a positive electrode terminal of the high-voltage battery 20 via the reactor 32. The boost converter 30 increases output voltage of the high-voltage battery 20 by on/off operation of the boost switches SCH, SCL.

The inverter 12 includes series connections of upper arm switches SUH, SVH, SWH and lower arm switches SUL, SVL, SWL for three phases. In the present embodiment, as the switches SUH to SWL, voltage controlled semiconductor switches, specifically, IGBTs are used. The switches SUH to SWL are connected with free-wheel diodes in parallel.

The emitter of the U-phase upper arm switch SUH is connected to the collector of the U-phase lower arm switch SUL. The connection point between the U-phase upper arm switch SUH and the U-phase lower arm switch SUL is connected to a U-phase input terminal of the motor generator 10. The emitter of the V-phase upper arm switch SVH is connected to the collector of the V-phase lower arm switch SUV. The connection point between the V-phase upper arm switch SVH and the V-phase lower arm switch SVL is connected to a V-phase input terminal of the motor generator 10. The emitter of the W-phase upper arm switch SWH is connected to the collector of the W-phase lower arm switch SWV. The connection point between the W-phase upper arm switch SWH and the W-phase lower arm switch SWL is connected to a W-phase input terminal of the motor generator 10.

The collectors of the upper arm switches SUH to SWH are connected by a positive electrode side bus 13 such as a bus bar. The positive electrode side bus 13 is connected to the collector of the upper arm boost switch SCH and the first terminal of the smoothing capacitor 31. The emitters of the lower arm switches SUL to SWL are connected by a negative electrode side bus 14 such as a bus bar. The negative electrode side bus 14 is connected to the emitter of the lower arm boost switch SCL, the second terminal of the smoothing capacitor 31, and the negative electrode terminal of the high-voltage battery 20.

The control device 40 is a microcomputer that is driven by electrical power supplied from a low-voltage battery 42, which is a DC power supply. The control device 40 operates the inverter 12 and the boost converter 30 to control torque of the motor generator 10 to a command torque Trq*. Specifically, the control device 40 generates operation signals GUH to GWL and outputs them to drive circuits of the switches SUH to SWL to turn on and off the switches SUH to SWL configuring the inverter 12. The control device 40 generates operation signals GCH, GCL and outputs them to drive circuits of the switches SCH, SCL to turn on and off the switches SCH, SCL configuring the boost converter 30.

The low-voltage battery 42 is a storage battery whose output voltage is lower than output voltage of the high-voltage battery 20, for example, a lead storage battery. In the present embodiment, the low-voltage battery 42 corresponds to a DC power supply.

An interface unit 44 has a function of electrically isolating a high voltage region (high-voltage side) including the motor generator 10, the inverter 12, the boost converter 30, and the high-voltage battery 20 and a low voltage region (low-voltage side) including the control device and the low-voltage battery 42 from each other and transmitting signals between the systems. The interface unit 44 may be, for example, a photocoupler.

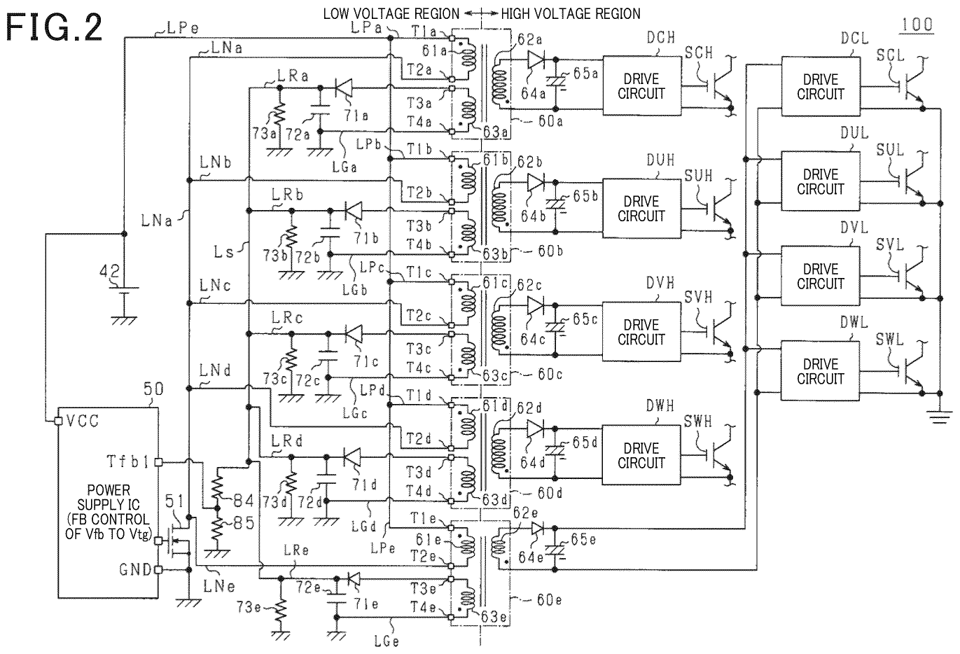

Next, with reference to FIG. 2, an isolated power supply device 100 will be described. The isolated power supply device 100 has a function of supplying electrical power to drive circuits DCH, DCL, DUH to DWL that drive the switches SCH, SCL, SUH to SWL while isolating the high voltage region and the low voltage region from each other. In the present embodiment, the isolated power supply device 100 is a flyback switching power supply.

The isolated power supply device 100 includes a power supply IC 50 and a control switch 51. The power supply IC 50 and the control switch are provided in the low voltage region. The power supply IC 50 turns on and off the control switch 51. The control switch 51 is a voltage controlled semiconductor switch, specifically, an N-channel MOSFET.

The isolated power supply device 100 includes upper arm transformers that supply electrical power to the upper arm drive circuits DCH, DUH, DVH, DWH and a lower arm transformer that supplies electrical power to the lower arm drive circuits DCL, DUL, DVL, DWL. The upper arm transformers are provided individually corresponding to the upper arm switches SCH, SUH, SVH, SWH. The lower arm transformer is provided as a transformer common to the lower arm switches SCL, SUL, SVL, SWL.

Specifically, the upper arm transformers are first to fourth transformers 60a, 60b, 60c, 60d. The lower arm transformer is a fifth transformer 60e. The first transformer 60a supplies electrical power to the boosting upper arm drive circuit DCH. The second transformer 60b supplies electrical power to the U-phase upper arm drive circuit DUH. The third transformer 60c supplies electrical power to the V-phase upper arm drive circuit DVH. The fourth transformer 60d supplies electrical power to the W-phase upper arm drive circuit DWH. The fifth transformer 60e supplies electrical power to the lower arm drive circuits DCL, DUL, DVL, DWL. It is noted that, in the present embodiment, the drive circuits DCH, DCL, DUH to DWL correspond to power feeding targets.

The first transformer 60a includes a first input winding 61a, a first output winding 62a, and a first feedback winding 63a. The first transformer 60a includes a common core around which the windings 61a, 62a, 63a are wound. The windings 61a, 62a, 63a are magnetically coupled by the common core.

As in the first transformer 60a, the second transformer 60b includes a second input winding 61b, a second output winding 62b, and a second feedback winding 63b that are magnetically coupled by a common core. As in the first transformer 60a, the third transformer 60c includes a third input winding 61c, a third output winding 62c, and a third feedback winding 63c that are magnetically coupled by a common core. As in the first transformer 60a, the fourth transformer 60d includes a fourth input winding 61d, a fourth output winding 62d, and a fourth feedback winding 63d that are magnetically coupled by a common core. As in the first transformer 60a, the fifth transformer 60e includes a fifth input winding 61e, a fifth output winding 62e, and a fifth feedback winding 63c that are magnetically coupled by a common core.

It is noted that the input windings 61a to 61e and the feedback windings 63a to 63e are provided in the low voltage region. The output windings 62a to 62e are provided in the high voltage region.

The transformers 60a to 60e are provided with a plurality of terminals. Output terminals of the first to fifth transformers 60a to 60e are connected with the corresponding first to fifth output windings 62a to 62e.

A first terminal T1a of the first transformer 60a is connected to a second terminal T2a of the first transformer 60a via the first input winding 61a. A third terminal T3a of the first transformer 60a is connected to a fourth terminal T4a of the first transformer 60a via the first feedback winding 63a. When an electrical potential of the first terminal T1a is higher than that of the second terminal T2a of the first transformer 60a, induced voltage is generated in the first feedback winding 63a so that an electrical potential of the fourth terminal T4a becomes higher than that of the third terminal T3a of the first transformer 60a.

A first terminal T1b of the second transformer 60b is connected to a second terminal T2b of the second transformer 60b via the second input winding 61b. A third terminal T3b of the second transformer 60b is connected to a fourth terminal T4b of the second transformer 60b via the second feedback winding 63b. When an electrical potential of the first terminal T1b is higher than that of the second terminal T2b of the second transformer 60b, induced voltage is generated in the second feedback winding 63b so that an electrical potential of the fourth terminal T4b becomes higher than that of the third terminal T3b of the second transformer 60b.

A first terminal T1c of the third transformer 60c is connected to a second terminal T2c of the third transformer 60c via the third input winding 61c. A third terminal T3c of the third transformer 60c is connected to a fourth terminal T4c of the third transformer 60c via the third feedback winding 63c. When an electrical potential of the first terminal T1c is higher than that of the second terminal T2c of the third 10) transformer 60c, induced voltage is generated in the third feedback winding 63c so that an electrical potential of the fourth terminal T4c becomes higher than that of the third terminal T3c of the first transformer 60c.

A first terminal T1d of the fourth transformer 60d is connected to a second terminal T2d of the fourth transformer 60d via the fourth input winding 61d. A third terminal T3d of the fourth transformer 60d is connected to a fourth terminal T4d of the fourth transformer 60d via the fourth feedback winding 63d. When an electrical potential of the first terminal T1d is higher than that of the second terminal T2d of the fourth 20) transformer 60d, induced voltage is generated in the fourth feedback winding 63d so that an electrical potential of the fourth terminal T4d becomes higher than that of the third terminal T3d of the fourth transformer 60d.

A first terminal T1e of the fifth transformer 60e is connected to a second terminal T2e of the fifth transformer 60e via the fifth input winding 61e. A third terminal T3e of the fifth transformer 60e is connected to a fourth terminal T4e of the fifth transformer 60e via the fifth feedback winding 63e. When an electrical potential of the first terminal T1e is higher than that of the second terminal T2e of the fifth transformer 60e, induced voltage is generated in the fifth feedback winding 63e so that an electrical potential of the fourth terminal T4e becomes higher than that of the third terminal T3e of the fifth transformer 60e.

An output terminal of the first transformer 60a is connected to the boosting upper arm drive circuit DCH via a first output diode 64a and a first output capacitor 65a. An output terminal of the second transformer 60b is connected to the U-phase upper arm drive circuit DUH via a second output diode 64a and a second output capacitor 65b. An output terminal of the third transformer 60c is connected to the V-phase upper arm drive circuit DVH via a third output diode 64c and a third output capacitor 65c. An output terminal of the fourth transformer 60d is connected to the W-phase upper arm drive circuit DWH via a fourth output diode 64d and a fourth output capacitor 65d. An output terminal of the fifth transformer 60e is connected to the lower arm drive circuits DCL, DUL, DVL, DWL via a fifth output diode 64e and a fifth output capacitor 65e.

The first terminals T1a to T1e of the transformers 60a to 60 e are connected to a positive electrode terminal of the low-voltage battery 42 via wires. Specifically, the first terminal T1e of the fifth transformer 60e is connected to the positive electrode terminal of the low-voltage battery 42 via a fifth positive electrode wire LPe. The first terminal T1a of the first transformer 60a is connected to the fifth positive electrode wire LPe via a first positive electrode wire LPa. That is, the first terminal T1a of the first transformer 60a is connected to the positive electrode terminal of the low-voltage battery 42 via the first and fifth positive electrode wires LPa, LPe. The first terminals T1b to T1d of the second to fourth transformers 60b to 60d are, similarly to the first terminal T1a of the transformers 60a, connected to the fifth positive electrode wires LPe via the corresponding second to fourth positive electrode wires LPb to LPd. That is, the first terminals T1b to T1d of the second to fourth transformers 60b to 60d are connected to the positive terminal of the low-voltage battery 42 via the fifth positive electrode wirer LPe and the corresponding second to fourth positive electrode wirers LPb to LPd. It is noted that the negative electrode side of the low-voltage battery 42 is connected to the ground.

The second terminals T2a to T2e of the transformers 60a to 60e are connected to the drain of the control switch 51 via wirings. Specifically, the second terminal T2a of the first transformer 60a is connected to the drain of the control switch 51 via a first negative electrode wiring LNa. The second terminals T2b to T2d of the second to fifth transformers 60b to 60e are connected to the first negative electrode wiring LNa via corresponding second to fifth negative electrode wirings LNb to LNd. That is, the second terminals T2b to T2d of the second to fifth transformers 60b to 60e are connected to the drain of the control switch 51 via the first negative electrode wiring LNa and the second to fifth negative electrode wirings LNb to LNd. The source of the control switch 51 is connected to the ground.

The third terminals T3a to T3e of the first to fifth transformers 60a to 60e are connected to an input side common wiring Ls via corresponding first to fifth feedback wrings LRa to LRe. The feedback wrings LRa to LRe and the input side common wiring Ls are provided in the low voltage region.

The first feedback wring LRa is provided with a first feedback diode 71a. The anode of the first feedback diode 71a is connected to the third terminal T3a of the first transformer 60a, and the cathode of the first feedback diode 71a is connected to the input side common wiring Ls. The second feedback wring LRb is provided with a second 20) feedback diode 71b. The anode of the second feedback diode 71b is connected to the third terminal T3b of the second transformer 60b, and the cathode of the second feedback diode 71b is connected to the input side common wiring Ls.

The third feedback wring LRc is provided with a third feedback diode 71c. The anode of the third feedback diode 71c is connected to the third terminal T3c of third transformer 60c, and the cathode of the third feedback diode 71c is connected to the input side common wiring Ls. The fourth feedback wring LRd is provided with a fourth feedback diode 71d. The anode of the fourth feedback diode 71d is connected to the third terminal T3d of the fourth transformer 60d, and the cathode of the fourth feedback diode 71d is connected to the input side common wiring Ls. The fifth feedback wring LRe is provided with a fifth feedback diode 71e. The anode of the fifth feedback diode 71e is connected to the third terminal T3e of the fifth transformer 60e, and the cathode of the fifth feedback diode 71e is connected to the input side common wiring Ls.

The fourth terminal T4a of the first transformer 60a is connected to the ground via a first ground wiring LGa. As in the case of the first transformer 60a, the fourth terminals T4b to T4e of the second to fifth transformers 60b to 60e are connected to the ground via corresponding second to fifth ground wirings LGb to LGe.

The isolated power supply device 100 includes first to fifth feedback capacitors 72a to 72e. The first feedback capacitor 72a connects the cathode of the first feedback diode 71a and the first ground wiring LGa. As in the case of the first feedback capacitor 72a, the second to fifth feedback capacitors 72b to 72e connect the cathodes of the corresponding second to fifth feedback diodes 71b to 71e and the corresponding second to fifth ground wirings LGb to LGe.

The isolated power supply device 100 includes bleeder resistors. The bleeder resistors are resistive elements that are provided to adjust the magnitudes of loads connected to the transformers 60a to 60e and performs a function of reducing variation of voltage generated in the feedback windings 63a to 63e. In the present embodiment, the isolated power supply device 100 includes first to fourth bleeder resistors 73a to 73d as upper arm bleeder resistors and a fifth bleeder resistor 73e as a lower bleeder resistor. The resistance value of the fifth bleeder resistor 73e is set to be lower than the resistance values of the first to fourth bleeder resistors 73a to 73d.

A first terminal of the first bleeder resistor 73a is connected to the first feedback wring LRa, and a second terminal of the first bleeder resistor 73a is connected to the ground. As in the case of the first bleeder resistor 73a, first terminals of the second to fifth bleeder resistors 73b to 73e are connected to the corresponding second to fifth feedback wrings LRb to LRe, and second terminals of the second to fifth bleeder resistors 73b to 73e are connected to the ground. It is noted that the first terminals of the bleeder resistors 73a to 73e are connected to the cathodes of the corresponding feedback diodes 71a to 71e.

The power supply IC 50 is one integrated circuit. While electrically isolating the low-voltage battery 42 and the drive circuits DCH, DCL, DUH to DWL from each other, the power supply IC 50 turns on and off the control switch 51 to supply electrical power to the drive circuits DCH, DCL, DUH to DWL. In this case, the power supply IC 50 turns on and off the control switch 51 to perform feedback control of a feedback control value Vfb to a target value Vtg. In the present embodiment, the power supply IC 50 sets a time ratio Ton/Tsw, where Tsw is one switching cycle of the control switch 51, and Ton is an on time period of the control switch 51. Then, the power supply IC 50 outputs an operation signal corresponding to the set time ratio to the gate of the control switch 51. In the present embodiment, the power supply IC 50 corresponds to a control unit.

It is noted that, in the present embodiment, the feedback control of the feedback control value Vfb to the target value Vtg turns on and off the control switch 51 so as to change the voltages generated in the output windings 62a to 62e by an amount corresponding to a deviation value between the feedback control value Vfb to the target value Vtg.

When the control switch 51 is turned on, power feeding is performed from the low-voltage battery 42 to the input windings 61a to 61e. During this, induced voltage is generated in the first feedback winding 63a so that an electrical potential of the fourth terminal T4a becomes higher than that of the third terminal T3a of the first transformer 60a. In this case, current flow to the first feedback winding 63a is restricted by the first feedback diode 71a, whereby magnetic energy is stored in the first transformer 60a. It is noted that, as in the case of the first feedback winding 63a, current flow to the first output winding 62a is restricted by the first output diode 64a.

As in the case of the first transformer 60a, when the control switch 51 is turned on, magnetic energy is stored in the second to fifth transformers 60b to 60e. Specifically, when the control switch 51 is turned on, induced voltage is generated in the second feedback winding 63b so that an electrical potential of the fourth terminal T4b becomes higher than that of the third terminal T3b of the second transformer 60b. In this case, current flow to the second feedback winding 63b is restricted by the second feedback diode 71b, whereby magnetic energy is stored in the second transformer 60b. When the control switch 51 is turned on, induced voltage is generated in the third feedback winding 63c so that an electrical potential of the fourth terminal T4c becomes higher than that of the third terminal T3c of the third transformer 60c. In this case, current flow to the third feedback winding 63c is restricted by the third feedback diode 71c, whereby magnetic energy is stored in the third transformer 60c.

When the control switch 51 is turned on, induced voltage is generated in the fourth feedback winding 63d so that an electrical potential of the fourth terminal T4d becomes higher than that of the third terminal T3d of the fourth transformer 60d. In this case, current flow to the fourth feedback winding 63d is restricted by the fourth feedback diode 71d, whereby magnetic energy is stored in the fourth 15 transformer 60d. When the control switch 51 is turned on, induced voltage is generated in the fifth feedback winding 63e so that an electrical potential of the fourth terminal T4e becomes higher than that of the third terminal T3e of the fifth transformer 60e. In this case, current flow to the fifth feedback winding 63e is restricted by the fifth 20) feedback diode 71e, whereby magnetic energy is stored in the fifth transformer 60e.

It is noted that when the control switch 51 is turned on, as in the case of the second to fifth feedback windings 63b to 63e, current flow to the second to fifth output windings 62b to 62e is restricted by the corresponding second to fifth output diodes 64b to 64e.

In contrast, when the control switch 51 is turned off, power feed from the low-voltage battery 42 to the input windings 61a to 61e is stopped. During this, induced voltage is generated in the first feedback winding 63a so that an electrical potential of the third terminal T3a becomes higher than that of the fourth terminal T4a of the first transformer 60a. Hence, current flows through the first feedback winding 63a. In addition, as in the case of the first feedback winding 63a, current flows through the first output winding 62a, whereby electrical power is supplied to the boosting upper arm drive circuit DCH.

As in the case of the first transformer 60a, when the control switch 51 is turned off, current flows through the second to fifth feedback windings 63b to 63e. Specifically, when the control switch 51 is turned off, induced voltage is generated in the second feedback winding 63b so that an electrical potential of the third terminal T3b becomes higher than that of the fourth terminal T4b of the second transformer 60b. Hence, current flows through the second feedback winding 63b. In addition, as in the case of the second feedback winding 63b, current flows through the second output winding 62b, whereby electrical power is supplied to the corresponding U-phase upper arm drive circuit DUH.

When the control switch 51 is turned off, induced voltage is generated in the third feedback winding 63c so that an electrical potential of the third terminal T3c becomes higher than that of the fourth terminal T4c of the third transformer 60c. Hence, current flows through the third feedback winding 63c. In addition, as in the case of the third feedback winding 63c, current flows through the third output winding 62b, whereby electrical power is supplied to the corresponding V-phase upper arm drive circuit DVH.

When the control switch 51 is turned off, induced voltage is generated in the fourth feedback winding 63d so that an electrical potential of the third terminal T3d becomes higher than that of the fourth terminal T4d of the fourth transformer 60d. Hence, current flows through the fourth feedback winding 63d. In addition, as in the case of the fourth feedback winding 63d, current flows through the fourth output winding 62d, whereby electrical power is supplied to the corresponding W-phase upper arm drive circuit DWH.

When the control switch 51 is turned off, induced voltage is generated in the fifth feedback winding 63e so that an electrical potential of the third terminal T3e becomes higher than that of the fourth terminal T4e of the fifth transformer 60e. Hence, current flows through the fifth feedback winding 63e. In addition, as in the case of the fifth feedback winding 63e, current flows through the fifth output winding 62e, whereby electrical power is supplied to the corresponding lower arm drive circuits DCL, DUL, DVL, DWL.

Incidentally, if variation occurs in the magnitudes of loads of the drive circuits DCH, DCL, DUH to DWL, there is a concern that controllability of output voltages of the transformers 60a to 60e is decreased.

Specifically, a state can be considered in which the switches SUH to SWL of the inverter 12 and the switches SCH, SCL of the boost converter 30 have different drive conditions. For example, there is a state in which although the switches SCH, SCL of the boost converter 30 are not driven, the switches SUH to SWL of the inverter 12 are driven. In this case, the magnitudes of loads of the boosting upper and lower arm drive circuits DCH, DCL are smaller than the magnitudes of loads of the upper and lower arm drive circuits DUH to DWL of the respective phases. Hence, for example, in the first transformer 60a corresponding to the boosting upper arm drive circuit DCH, compared with the second to fourth transformers 60b to 60d corresponding to the upper arm drive circuits DUH to DWH of the respective phases, output voltage is likely to increase due to excessive supply of magnetic energy.

In addition, for example, there is a case in which, among the switches SUH to SWL of the inverter 12, only the U, V phase upper and lower arm switches SUH, SVH, SUL, SVL are driven. In this case, the magnitudes of loads of the U, V phase upper and lower arm drive circuits DUH, DVH, DUL, DVL are larger than the magnitudes of loads of the W phase upper and lower arm drive circuits DWH, DWL. Hence, for example, in the second and third transformers 60b, 60c corresponding to the U, V phase upper arm drive circuits DUH, DVH, output voltage is likely to lower due to insufficient supply of magnetic energy compared with the fourth transformer 60d corresponding to the W phase upper arm drive circuit DWH. As described above, in a state in which variation occurs in the magnitudes of loads of the drive circuits DCH, DCL, DUH to DWL, output voltages of the transformers 60a to 60e are likely to vary.

Herein, unlike the present embodiment, it can be considered that the control switch 51 may be turned on and off based on an output voltage of any one of the transformers 60a to 60e. In this case, the control switch 51 is turned on and off so that the output voltage of the transformer to be controlled out of the transformers 60a to 60e reaches a target output voltage. In contrast, an output voltage of the transformer not to be controlled out of the transformers 60a to 60e varies by the difference between the output voltage of the transformer to be controlled and the target output voltage. Hence, in a state described above in which variation is likely to occur in output voltages of the transformers 60a to 60e, there is a concern that output voltages of the transformers not to be controlled out of the transformers 60a to 60e excessively increase or decrease with respect to the target output voltage. It is noted that, for example, output voltages of the transformers 60a to 60e are voltages generated in the output windings 62a to 62e, and the target output voltage is set within a voltage range defined by an upper limit voltage and a lower limit voltage of voltages generated in the output windings 62a to 62e.

Hence, in the present embodiment, the isolated power supply device 100 uses voltages generated in the feedback windings 63a to 63e to turn on and off the control switch 51. Specifically, the isolated power supply device 100 includes a first voltage dividing resistor 84 and a second voltage dividing resistor 85. A first terminal of the first voltage dividing resistor 84 is connected to the input side common wiring Ls, and a second terminal of the first voltage dividing resistor 84 is connected to a first terminal of the second voltage dividing resistor 85. A second terminal of the second voltage dividing resistor 85 is connected to the ground. A connection point between the second terminal of the first voltage dividing resistor 84 and the first terminal of the second voltage dividing resistor 85 is connected to the power supply IC 50.

The power supply IC 50 turns on and off the control switch 51 based on a voltage value of the input side common wiring Ls. In the present embodiment, the power supply IC 50 acquires voltage dividing values of the first and second voltage dividing resistors 84, 85. The power supply IC 50 sets a time ratio of the control switch 51 based on the acquired voltage dividing values. Hence, compared with the case in which the time ratio of the control switch 51 is set based on a voltage generated in a feedback winding of any one of the transformers 60a to 60e, voltages generated in a number of feedback windings are used for setting the time ratio of the control switch 51.

In the present embodiment, magnetic energy stored in the transformers 60a to 60e is transferred between the transformers 60a to 60e. Specifically, in the configuration of the isolated power supply device 100 described above, a closed circuit including the feedback windings 63a to 63e, the feedback wrings LRa to LRe, and the input side common wiring Ls is formed. In this case, when a current flows through the closed circuit, between the transformers 60a to 60e, magnetic energy is transferred from the transformer having high magnetic energy to the transformer having low magnetic energy. Hence, the magnetic energy stored in the transformers 60a to 60e is suppressed from being excessive or being insufficient. Thus, variation in output voltages of the transformers 60a to 60e can be reduced.

In the present embodiment, corresponding to the feedback windings 63a to 63e, the feedback diodes 71a to 71e and the feedback capacitors 72a to 72e are provided. Currents output from the third terminals T3a to T3e of the transformers 60a to 60e are rectified by the corresponding feedback diodes 71a to 71e, and the corresponding feedback capacitors 72a to 72e are charged. In this case, in the closed circuit including the feedback windings 63a to 63e, the feedback wrings LRa to LRe, and the input side common wiring Ls, charges stored in the feedback capacitors 72a to 72e are transferred, whereby current flows. Hence, magnetic energy is transferred between the transformers 60a to 60e.

It is noted that it can be considered that when a closed circuit including the input windings 61a to 61e, the positive electrode wirings LPa to LPe, the negative electrode wirings LNa to LNe, the control switch 51, and the low-voltage battery 42 is formed, and current flows through the closed circuit, magnetic energy is transferred between the transformers 60a to 60e.

However, in this case, there is a concern that when a large current flows to the positive electrode wirings LPa to LPe and the negative electrode wirings LNa to LNe to supply electrical power from the low-voltage battery 42 to the transformers 60a to 60e, the amount of a voltage drop in the formed closed circuit increases. In addition, when currents flow to the wirings LPa to LPe, LNa to LNe in response to on/off operation of the control switch 51, a change rate of the currents flowing through the wirings LPa to LPe, LNa to LNe increases. Hence, there is a concern that, due to inductance components of the input windings 61a to 61e, current flow through the closed circuit including the input windings 61a to 61e and the like is suppressed. Hence, in the present embodiment, the closed circuit including the feedback windings 63a to 63e, the feedback wrings LRa to LRe, and the input side common wiring Ls is formed. It is noted that, in the present embodiment, the feedback windings 63a to 63e correspond to control windings, and the feedback wrings LRa to LRe correspond to control wirings.

According to the present embodiment described above in detail, the following effects can be obtained.

According to the present embodiment, while variation in output voltages of the transformers 60a to 60e is reduced, compared with the case in which a feedback winding is provided to any one of the transformers 60a to 60e, the number of the transformers not to be controlled is decreased. As a result, the output voltages of the transformers 60a to 60e are suppressed from being excessively high and being excessively low. Furthermore, controllability of the output voltages of the transformers 60a to 60e can be increased.

It can be considered that on/off control of the control switch 51 is performed based on voltages generated in the output windings 62a to 62e. However, the power supply IC 50 is provided in the low voltage region, and the output windings 62a to 62e are provided in the high voltage region. Hence, in order to transfer the voltages generated in the output windings 62a to 62e to the power supply IC 50, it is required to add an isolating and transmitting unit that transmits voltage values of the output windings 62a to 62e to the power supply IC 50 while electrically isolating the output windings 62a to 62e and the power supply IC 50 from each other.

In this regard, in the present embodiment, the feedback windings 63a to 63e are provided corresponding to the transformers 60a to 60e. The third terminals T3a to T3e of the transformers 60a to 60e are connected to the input side common wiring Ls via the corresponding feedback wrings LRa to LRe. Then, a voltage value of the input side common wiring Ls is transferred to the power supply IC 50. Hence, since the isolating and transmitting unit is not required to be added, the number of components of the isolated power supply device 100 is suppressed from increasing. In addition to this, according to the present embodiment, controllability of the output voltages of the transformers 60a to 60e can be increased as described above. That is, while the number of components of the isolated power supply device 100 is suppressed from increasing, controllability of the output voltages of the transformers 60a to 60e can be increased.

When current flows through the closed circuit including the feedback windings 63a to 63e, the feedback wrings LRa to LRe, and the input side common wiring Ls, there is a concern that, due to inductance components of the feedback windings 63a to 63e, current flow through the closed circuit is suppressed. In this case, there is a concern that the magnetic energy stored in the transformers 60a to 60e is not sufficiently transferred.

In this regard, according to the present embodiment, in the closed circuit including the feedback windings 63a to 63e, the feedback wrings LRa to LRe, and the input side common wiring Ls, charges stored in the feedback capacitors 72a to 72e are transferred, whereby current flows. Hence, the magnetic energy stored in the transformers 60a to 60e is transferred. Thus, while preventing current from flowing through the closed circuit due to the inductance components of the feedback windings 63a to 63e is suppressed, the magnetic energy can be appropriately transferred between the transformers 60a to 60e.

A configuration can be considered in which voltage dividing resistors are provided corresponding to the feedback windings 63a to 63e. In this case, the voltage dividing resistors are connected to the feedback wrings LRa to LRe. In this case, there is a concern that a closed circuit including the feedback windings 63a to 63e, the feedback wrings LRa to LRe, the input side common wiring Ls, and the voltage dividing resistors is formed, whereby current flow through the closed circuit is suppressed. In this regard, according to the present embodiment, the input side common wiring Ls is connected to the first terminal of the first voltage dividing resistor 84. Hence, without connection via the first and second voltage dividing resistors 84, 85, the closed circuit including the feedback windings 63a to 63e, the feedback wrings LRa to LRe, the input side common wiring Ls is formed. Hence, compared with the configuration in which voltage dividing resistors are provided corresponding to the feedback windings 63a to 63e, suppression of current flow through the closed circuit can be avoided.

It can be considered that when current flows through a closed circuit including a bleeder resistor, which is a heat generation component, magnetic energy stored in the transformers 60a to 60e is transferred. Herein, in order to suppress a path of the closed circuit including a bleeder resistor from being lengthened, it is desirable that the bleeder resistor is disposed in the vicinity of the feedback windings 63a to 63e. In this regard, the feedback windings 63a to 63e are connected to the input side common wiring Ls via the feedback wrings LRa to LRe. Hence, it can be considered that the bleeder resistor can be disposed in the vicinity of the feedback windings 63a to 63e in the case in which the bleeder resistor is connected to the feedback wrings LRa to LRe directly connected to the feedback windings 63a to 63e, compared with the case in which the bleeder resistor is connected to the input side common wiring Ls.

Hence, in the present embodiment, the bleeder resistors 73a to 73e are connected to the corresponding feedback wrings LRa to LRe. Hence, while the path of the closed circuit including the bleeder resistors 73a to 73e is suppressed from being lengthened, the bleeder resistors 73a to 73e can be disposed.

In addition, in the present embodiment, bleeder resistors are provided corresponding to the feedback windings 63a to 63e. Specifically, the bleeder resistors 73a to 73e corresponding to the feedback wrings LRa to LRe are connected. Hence, the bleeder resistors 73a to 73e, which are heat generation components, can be dispersedly disposed.

The first to fourth transformers 60a to 60d are individually provided corresponding to the upper arm switches SCH, SUH, SVH, SWH. The fifth transformer 60e is provided as a transformer common to the lower arm switches SCL, SUL, SVL, SWL. This configuration can be considered that the magnitude of a load connected to the fifth transformer 60e is larger than the magnitudes of loads connected to the first to fourth transformers 60a to 60d.

In this regard, in the present embodiment, the resistance value of the fifth bleeder resistor 73e is set to be lower than the resistance values of the first to fourth bleeder resistors 73a to 73d. Hence, unbalance between the magnitude of a load connected to the fifth transformer 60e and the magnitudes of loads connected to the first to fourth transformers 60a to 60d can be appropriately suppressed. Hence, variation in voltages caused in the feedback windings 63a to 63e can be appropriately reduced.

### Modifications of First Embodiment

The upper arm transformers may not be individually provided corresponding to the upper arm switches SCH, SUH, SVH, SWH but be provided as a common transformer for the upper arm switches SCH, 25 SUH, SVH, SWH.

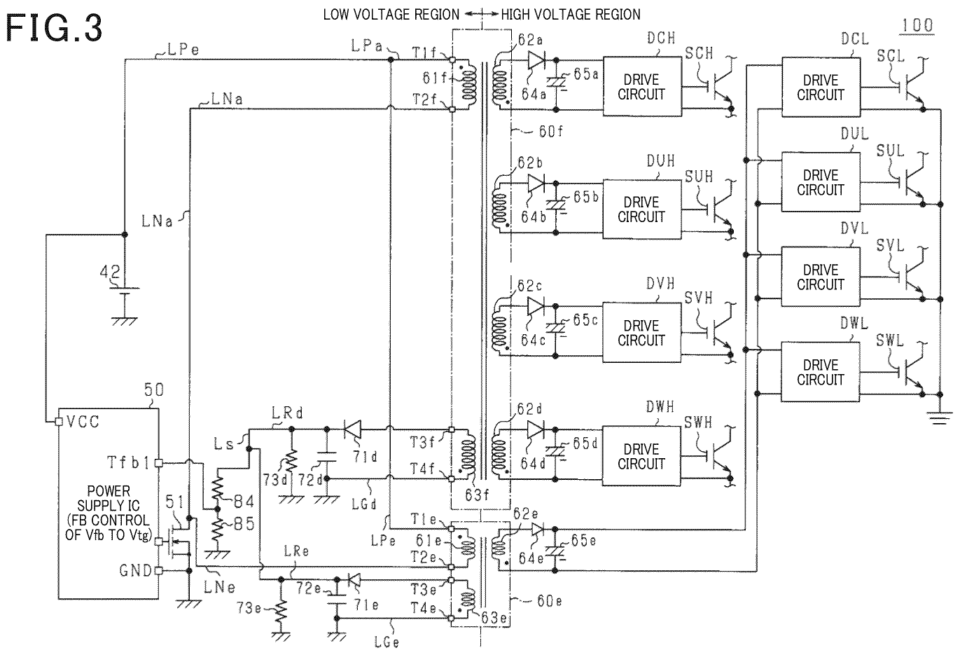

Specifically, as illustrated in FIG. 3, the upper arm transformer is the sixth transformer 60f. The sixth transformer 60f supplies electrical power to the upper arm drive circuits DCH, DUH to DWH. The sixth transformer 60f includes a sixth input winding 61f and a sixth feedback winding 63f. The sixth transformer 60f includes a common core around which the sixth input winding 61f, the output windings 62a to 62d, and the sixth feedback winding 63f are wound. The windings 61f, 62a to 62d, 63f are magnetically coupled by the common core. It is noted that, in FIG. 3, the same component as that illustrated in FIG. 2 is denoted by the same reference sign for the sake of convenience.

The sixth transformer 60f is provided with first to fourth terminals T1f to T4f. A first terminal T1f of the sixth transformer 60f is connected to a second terminal T2f of the sixth transformer 60f via the sixth input winding 61f. A third terminal T3f of the sixth transformer 60f is connected to a fourth terminal T4f of the sixth transformer 60f via the sixth feedback winding 63f. When an electrical potential of the first terminal T1f is higher than that of the second terminal T2f of the sixth transformer 60f, induced voltage is generated in the sixth feedback winding 63f so that an electrical potential of the fourth terminal T4f becomes higher than that of the third terminal T3f of the sixth transformer 60f.

The first terminal Tf1 of the sixth transformer 60f is connected to the positive electrode terminal of the low-voltage battery 42 via the first and fifth positive electrode wirings LPa, LPe. The second terminal T2f of the sixth transformer 60f is connected to the drain of the control switch 51 via the first negative electrode wiring LNa. The third terminal T3f of the sixth transformer 60f is connected to the input side common wiring Ls via the fourth feedback wring LRd. The fourth 20) terminal T4f of the sixth transformer 60f is connected to the ground via the fourth ground wiring LGd.

According to the present embodiment, as an upper arm transformer, the sixth transformer 60f is provided. Hence, compared with the configuration in which the first to fourth transformers 60a to 60d are provided, the number of transformers provided as upper arm transformers can be decreased. In addition, while variation in output voltages of the fifth and sixth transformers 60e, 60f is suppressed from occurring, the number of transformers not to be controlled can be decreased compared with a case in which a feedback winding is provided to any one of the fifth and sixth transformers 60e, 60f. As a result, while the number of transformers provided as upper arm transformers is decreased, controllability of output voltages of the fifth and sixth transformers 60e, 60f can be increased.

Instead of providing the feedback windings 63a to 63e corresponding to the transformers 60a to 60e, feedback windings may be provided corresponding to at least two of the transformers 60a to 60e.

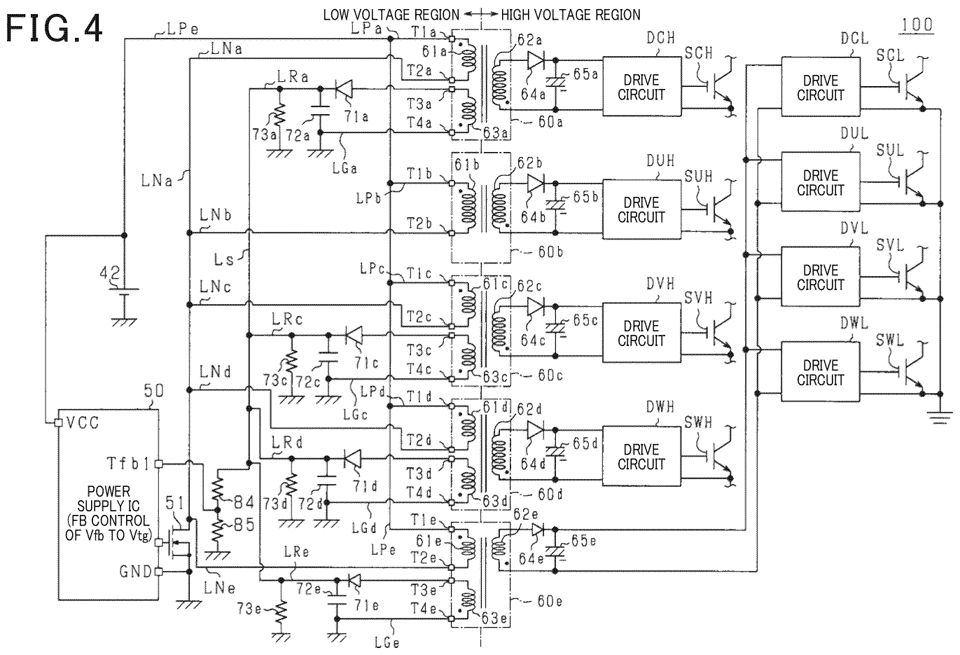

For example, as illustrated in FIG. 4, the first, third, fourth, and fifth feedback windings 63a, 63c, 63d, 63d may be provided corresponding to the first, third, fourth, and fifth transformers 60a, 60c, 60d, 60e out of the transformers 60a to 60e, and the second transformer 60b may not be provided with the feedback winding. It is noted that, in FIG. 4, the same component as that illustrated in FIG. 2 is denoted by the same reference sign for the sake of convenience.

According to the present embodiment, compared with the configuration in which the feedback windings 63a to 63e are provided corresponding to the transformers 60a to 60e, the number of transformers provided with the feedback windings is decreased. Hence, compared with the configuration in which the feedback windings 63a to 63e are provided corresponding to the transformers 60a to 60e, the number of components of the isolated power supply device 100 can be decreased. In addition, while change in output voltages of the first, third, fourth, and fifth transformers 60a, 60c, 60d, 60e is suppressed from occurring, the number of transformers not to be controlled can be decreased compared with a case in which a feedback winding is provided to any one of the transformers 60a to 60e. As a result, while the number of components of the isolated power supply device 100 is decreased, controllability of output voltages of the first, third, fourth, and fifth transformers 60a, 60c, 60d, 60e can be increased.

Instead of the configuration in which first and second voltage dividing resistors 84, 85 are connected to the input side common wiring Ls, a configuration in which voltage dividing resistors are provided corresponding to the feedback wrings LRa to LRe may be employed.

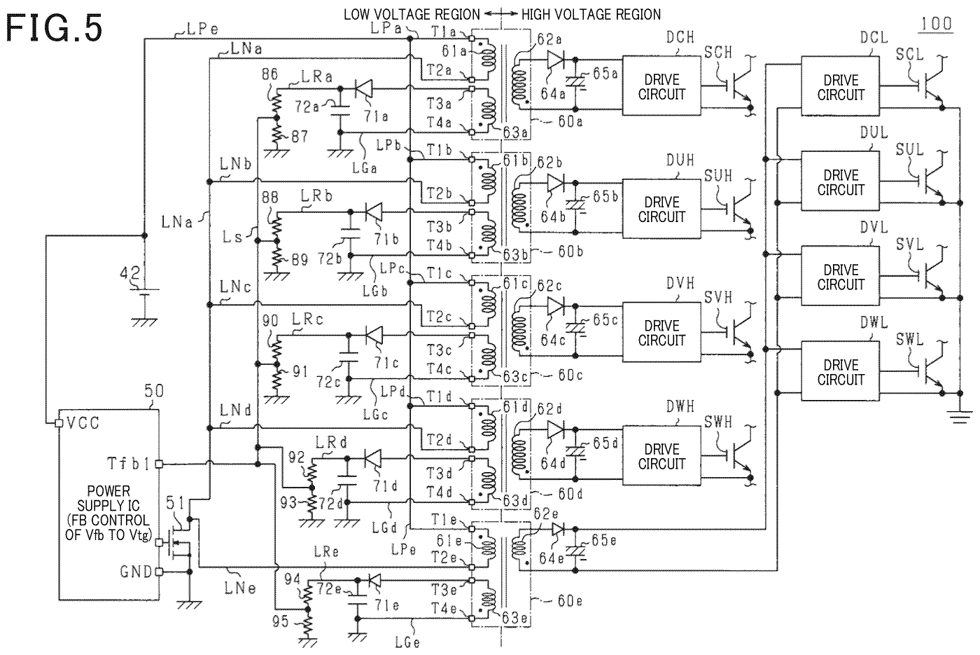

For example, as illustrated in FIG. 5, the isolated power supply device 100 includes third to twelfth voltage dividing resistors 86 to 95. It is noted that, in FIG. 5, the same component as that illustrated in FIG. 2 is denoted by the same reference sign for the sake of convenience.

The third voltage dividing resistor 86 and the fourth voltage dividing resistor 87 are provided corresponding to the first feedback wring LRa. A first terminal of the third voltage dividing resistor 86 is connected to the first feedback wring LRa. A second terminal of the third voltage dividing resistor 86 is connected to the input side common wiring Ls and a first terminal of the fourth voltage dividing resistor 87. A second terminal of the fourth voltage dividing resistor 87 is connected to the ground. The fifth voltage dividing resistor 88 and the sixth voltage dividing resistor 89 are provided corresponding to the second feedback wring LRb. A first terminal of the fifth voltage dividing resistor 88 is connected to the second feedback wring LRb. A second terminal of the fifth voltage dividing resistor 88 is connected to the input side common wiring Ls and a first terminal of the sixth voltage dividing resistor 89. A second terminal of the sixth voltage dividing resistor 89 is connected to the ground.

The seventh voltage dividing resistor 90 and the eighth voltage dividing resistor 91 are provided corresponding to the third feedback wring LRc. A first terminal of the seventh voltage dividing resistor 90 is connected to the third feedback wring LRc. A second terminal of the seventh voltage dividing resistor 90 is connected to the input side common wiring Ls and a first terminal of eighth voltage dividing resistor 91. A second terminal of the eighth voltage dividing resistor 91 is connected to the ground. The ninth voltage dividing resistor 92 and the tenth voltage dividing resistor 93 are provided corresponding to the fourth feedback wring LRd. A first terminal of the ninth voltage dividing resistor 92 is connected to the fourth feedback wring LRb. A second terminal of the ninth voltage dividing resistor 92 is connected to the input side common wiring Ls and a first terminal of the tenth voltage dividing resistor 93. A second terminal of the tenth voltage dividing resistor 93 is connected to the ground. The eleventh voltage dividing resistor 94 and the twelfth voltage dividing resistor 95 are provided corresponding to the fifth feedback wring LRe. A first terminal of the eleventh voltage dividing resistor 94 is connected to the fifth feedback wring LRe. A second terminal of the eleventh voltage dividing resistor 94 is connected to the input side common wiring Ls and a first terminal of the twelfth voltage dividing resistor 95. A second terminal of the twelfth voltage dividing resistor 95 is connected to the ground.

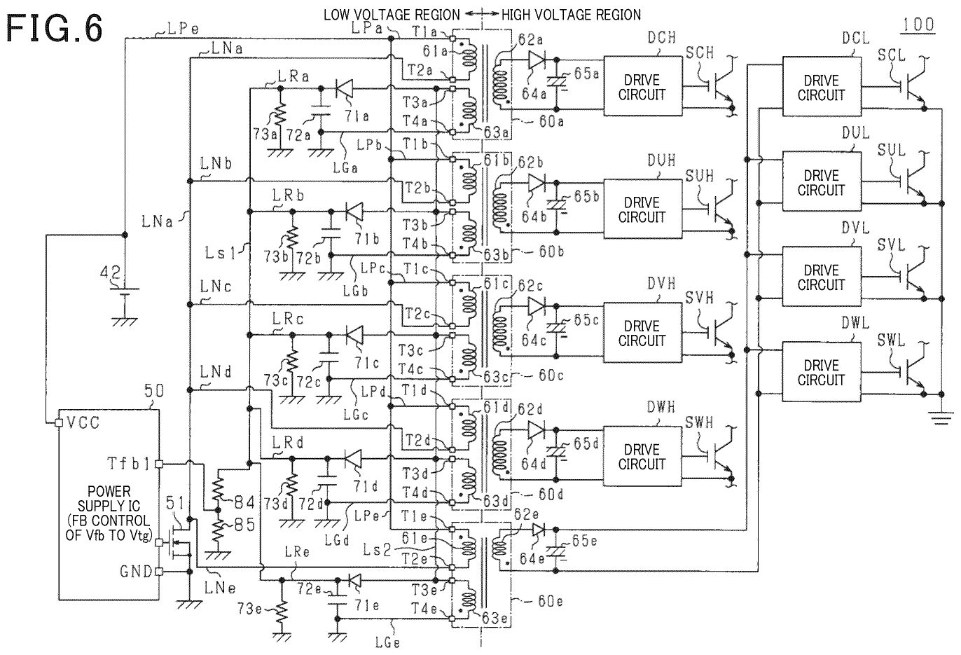

The configuration of the common wiring connecting the feedback wrings LRa to LRe may be modified. For example, as illustrated in FIG. 6, the isolated power supply device 100 may be provided with a first common wiring Ls1 and a second common wiring Ls2. The first common wiring Ls1 corresponds to the input side common wiring Ls in FIG. 2. The second common wiring Ls2 is connected to the feedback wrings LRa to LRe. Herein, the third terminals T3a to T3e of the transformers 60a to 60e are connected via the second common wiring Ls2. In addition, the anodes of the feedback diodes 71a to 71e are connected to the second common wiring Ls2. It is noted that, in FIG. 6, the same component as that illustrated in FIG. 2 is denoted by the same reference sign for the sake of convenience.

There is a concern that when the path of a first closed circuit including the feedback windings 63a to 63e, the feedback wrings LRa to LRe, and the first common wiring Ls1 is lengthened, the amount of a voltage drop in the first closed circuit increases, whereby current flow through the first closed circuit is suppressed. In this regard, according to the present embodiment, the third terminals T3a to T3e of the transformers 60a to 60e are connected via the second common wiring Ls2. Hence, a second closed circuit including the feedback windings 63a to 63e and the second common wiring Ls2 is formed. In this case, the path of the second closed circuit is suppressed from being longer than the path of the first closed circuit. Thus, while the amount of a voltage drop in the closed circuit is suppressed from increasing, magnetic energy stored in the transformers 60a to 60e can be transferred.

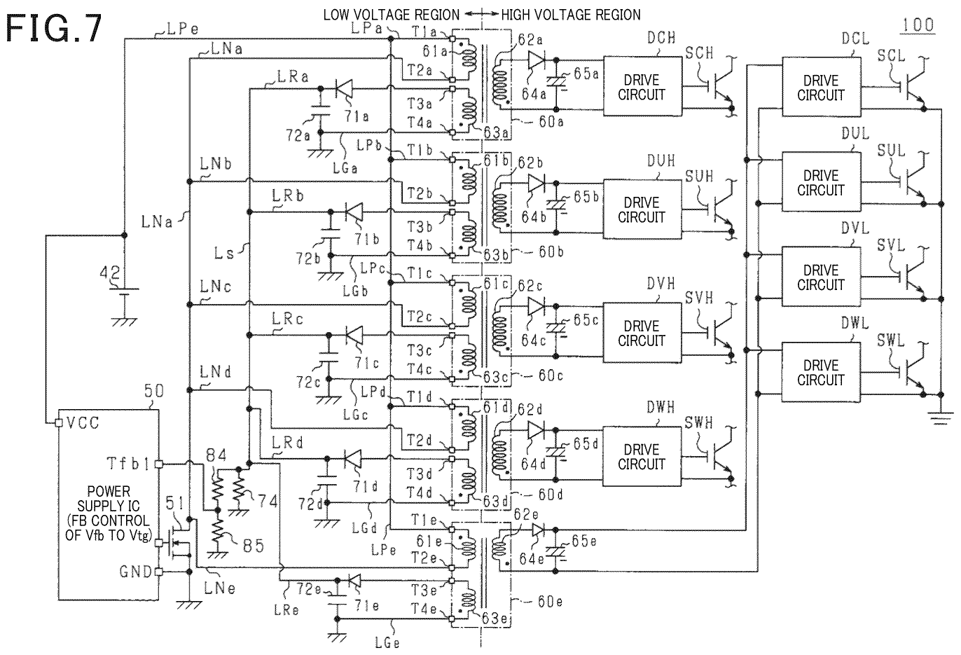

The bleeder resistors may not be connected to the feedback wrings LRa to LRe, but a bleeder resistor may be connected to the input side common wiring Ls. In the present embodiment, as illustrated in FIG. 7, the isolated power supply device 100 includes a common bleeder resistor 74. A first terminal of the common bleeder resistor 74 is connected to the input side common wiring Ls. A second terminal of the common bleeder resistor 74 is connected to the ground. It is noted that, in FIG. 7, the same component as that illustrated in FIG. 2 is denoted by the same reference sign for the sake of convenience.

According to the present embodiment, the first terminal of the common bleeder resistor 74 is connected to the input side common wiring Ls. According to this configuration, since no bleeder resistor is provided corresponding to the feedback wrings LRa to LRe, compared with the case in which bleeder resistors are connected to feedback wrings LRa to LRe, the number of the bleeder resistors can be decreased.

The bleeder resistors may not be provided corresponding to the feedback windings 63a to 63e but be provided corresponding to one, two, three, or four of the feedback windings 63a to 63e.

The switches SCH, SCL, SUH to SWL configuring the inverter 12 and the boost converter 30 are not limited to IGBTs and may be, for example, N-channel MOSFETs configured by Si.

The lower arm transformer may not be a common transformer for the lower arm switches SCL, SUL, SVL, SWL but be, for example, transformers individually provided corresponding to the lower arm switches SCL, SUL, SVL, SWL. It is noted that as a case in which lower arm transformers are individually provided, a case can be considered in which the switches SCH, SCL, SUH to SWL are not IGBTs but, for example, N-channel MOSFETs configured by a SiC (silicon carbide) based material, a GaN (gallium nitride) based material, or the like.

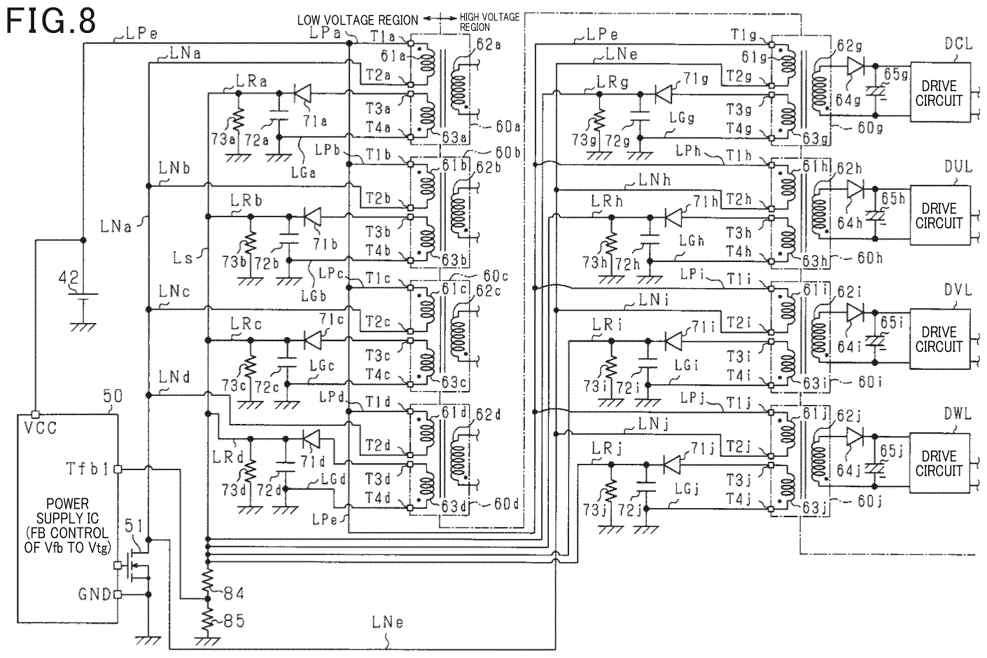

In this case, as illustrated in FIG. 8, the isolated power supply device 100 includes, as lower arm transformers, seventh to tenth transformers 60g to 60j. It is noted that, in FIG. 8, the same component as that illustrated in FIG. 2 is denoted by the same reference sign for the sake of convenience. In addition, in FIG. 8, the switches SCH, SCL, SUH to SWL and the like are not shown.

The seventh transformer 60g supplies electrical power to the boosting lower arm drive circuit DCL. The eighth transformer 60h supplies electrical power to the U-phase lower arm drive circuit DUL. The ninth transformer 60i supplies electrical power to the V-phase lower arm drive circuit DVL. The tenth transformer 60j supplies electrical power to the W-phase lower arm drive circuit DWL.

The seventh transformer 60g includes a seventh input winding 61g, a seventh output winding 62g, and a seventh feedback winding 63g that are magnetically coupled by a common core. The eighth transformer 60h includes an eighth input winding 61h, an eighth output winding 62h, and an eighth feedback winding 63h that are magnetically coupled by a common core. The ninth transformer 60i includes a ninth input winding 61j, a ninth output winding 62j, and a ninth feedback winding 63j that are magnetically coupled by a common core. The tenth transformer 60j includes a tenth input winding 61j, a tenth output winding 62j, and a tenth feedback winding 63j that are magnetically coupled by a common core.

It is noted that the seventh to tenth input windings 61g to 61j and the seventh to tenth feedback windings 63g to 63j are provided in the low voltage region. The seventh to tenth output windings 62g to 62j are provided in the high voltage region.

An output terminal of the seventh transformer 60g is connected to the boosting lower arm drive circuit DCL via a seventh output diode 64g and a seventh output capacitor 65g. An output terminal of the eighth transformer 60h is connected to the U-phase lower arm drive circuit DUL via an eighth output diode 64h and an eighth output capacitor 65h. An output terminal of the ninth transformer 60i is connected to the V-phase lower arm drive circuit DVL via a ninth output diode 64i and a ninth output capacitor 65i. An output terminal of the tenth transformer 60j is connected to the W-phase lower arm drive circuit DWL via a tenth output diode 64j and a tenth output capacitor 65j.

The seventh transformer 60g is provided with first to fourth terminals T1g to T4g. The first terminal T1g of the seventh transformer 60g is connected to the second terminal T2g of the seventh transformer 60g via the seventh input winding 61g. The third terminal T3g of the seventh transformer 60g is connected to the fourth terminal T4g of the seventh transformer 60g via the seventh feedback winding 63g. When an electrical potential of the first terminal T1g is higher than that of the second terminal T2g of the seventh transformer 60g, induced voltage is generated in the seventh feedback winding 63g so that an electrical potential of the fourth terminal T4g becomes higher than that of the third terminal T3g of the seventh transformer 60g.

The eighth transformer 60h is provided with first to fourth terminals T1h to T4h. The first terminal T1h of the eighth transformer 60h is connected to the second terminal T2h of the eighth transformer 60h via the eighth input winding 61h. The third terminal T3h of the eighth transformer 60h is connected to the fourth terminal T4h of the eighth transformer 60h via the eighth feedback winding 63h. When an electrical potential of the first terminal T1h is higher than that of the second terminal T2h of the eighth transformer 60h, induced voltage is generated in the eighth feedback winding 63h so that an electrical potential of the fourth terminal T4h becomes higher than that of the third terminal T3h of the eighth transformer 60h.

The ninth transformer 60i is provided with first to fourth terminals T1i to T4i. The first terminal T1i of the ninth transformer 60i is connected to the second terminal T2i of the ninth transformer 60i via the ninth input winding 61i. The third terminal T3i of the ninth transformer 60i is connected to the fourth terminal T4i of the ninth transformer 60i via the ninth feedback winding 63i. When an electrical potential of the first terminal T1i is higher than that of the second terminal T2i of the ninth transformer 60i, induced voltage is generated in the ninth feedback winding 63i so that an electrical potential of the fourth terminal T4i becomes higher than that of the third terminal T3i of the ninth transformer 60i.

The tenth transformer 60j is provided with first to fourth terminals T1j to T4j. The first terminal T1j of the tenth transformer 60j is connected to the second terminal T2j of the tenth transformer 60j via the tenth input winding 61j. The third terminal T3j of the tenth transformer 60j is connected to the fourth terminal T4j of the tenth transformer 60j via the tenth feedback winding 63j. When an electrical potential of the first terminal T1j is higher than that of the second terminal T2j of the tenth transformer 60j, induced voltage is generated in the tenth feedback winding 63j so that an electrical potential of the fourth terminal T4j becomes higher than that of the 5 third terminal T3j of the tenth transformer 60j.

The first terminal T1g of the seventh transformer 60g is connected to the positive electrode terminal of the low-voltage battery 42 via the fifth positive electrode wiring LPe. The second terminal T2g of the seventh transformer 60g is connected to the drain of the control 10) switch 51 via the first and fifth negative electrode wirings LNa, LNe. The third terminal T3g of the seventh transformer 60g is connected to the input side common wiring Ls via the seventh feedback wring LRg. The fourth terminal T4g of the seventh transformer 60g is connected to the ground via the seventh ground wiring LGg.

The first terminal T1h of the eighth transformer 60h is connected to the fifth positive electrode wiring LPe via an eighth positive electrode wiring LPh. That is, the first terminal T1h of the eighth transformer 60h is connected to the positive electrode terminal of the low-voltage battery 42 via the fifth and eighth positive electrode wirings LPe, LPh. The second terminal T2h of the eighth transformer 60h is connected to the fifth negative electrode wirings LNe via an eighth negative electrode wiring LNh. That is, the second terminal T2h of the eighth transformer 60h is connected to the drain of the control switch 51 via the first, fifth, and eighth negative electrode wirings LNa, LNe, LNh. The third terminal T3h of the eighth transformer 60h is connected to the input side common wiring Ls via the eighth feedback wring LRh. The fourth terminal T4h of the eighth transformer 60h is connected to the ground via the eighth ground wiring LGh.

The first terminal T1i of the ninth transformer 60i is connected to the fifth positive electrode wiring LPe via a ninth positive electrode wiring LPi. That is, the first terminal T1i of the ninth transformer 60i is connected to the positive electrode terminal of the low-voltage battery 42 via the fifth and ninth positive electrode wirings LPe, LPi. The second terminal T2i of the ninth transformer 60i is connected to the fifth negative electrode wiring LNe via a ninth negative electrode wiring LNi. That is, the second terminal T2i of the ninth transformer 60i is connected to the drain of the control switch 51 via the first, fifth, and ninth negative electrode wirings LNa, LNe, LNi. The third terminal T3i of the ninth transformer 60i is connected to the input side common wiring Ls via the ninth feedback wring LRi. The fourth terminal T4i of the ninth transformer 60i is connected to the ground via the ninth ground wiring LGi.

The first terminal T1j of the tenth transformer 60j is connected to the fifth positive electrode wiring LPe via a tenth positive electrode wiring LPj. That is, the first terminal T1j of the tenth transformer 60j is connected to the positive electrode of the low-voltage battery 42 via the fifth and tenth positive electrode wirings LPe, LPj. The second terminal T2j of the tenth transformer 60j is connected to the fifth negative electrode wirings LNe via a tenth negative electrode wiring LNj. That is, the second terminal T2j of the tenth transformer 60j is connected to the drain of the control switch 51 via the first, fifth, and tenth negative electrode wirings LNa, LNe, LNj. The third terminal T3j of the tenth transformer 60j is connected to the input side common wiring Ls via the tenth feedback wring LRj. The fourth terminal T4j of the tenth transformer 60j is connected to the ground via the tenth ground wiring LGj.

The seventh feedback wring LRg is provided with a seventh feedback diode 71g. The anode of the seventh feedback diode 71g is connected to the third terminal T3g of the seventh transformer 60g. The cathode of the seventh feedback diode 71g is connected to the input side common wiring Ls. The eighth feedback wring LRh is provided with an eighth feedback diode 71h. The anode of the eighth feedback diode 71h is connected to the third terminal T3h of the eighth transformer 60h. The cathode of the eighth feedback diode 71h is connected to the input side common wiring Ls. The ninth feedback wring LRi is provided with a ninth feedback diode 71i. The anode of the ninth feedback diode 71i is connected to the third terminal T3i of the ninth transformer 60i. The cathode of the ninth feedback diode 71i is connected to the input side common wiring Ls. The tenth feedback wring LRj is provided with a tenth feedback diode 71j. The anode of the tenth feedback diode 71j is connected to the third terminal T3j of the tenth transformer 60j. The cathode of the tenth feedback diode 71j is connected to the input side common wiring Ls.

The isolated power supply device 100 includes seventh to tenth feedback capacitors 72g to 72j. The seventh feedback capacitor 72g connects the cathode of the seventh feedback diode 71g and the seventh ground wiring LGg. As in the case of the seventh feedback capacitor 72g, the eight to tenth feedback capacitors 72h to 72j connect the cathodes of the corresponding eight to tenth feedback diodes 71h to 71j and the corresponding eight to tenth ground wirings LGh to LGj.

The isolated power supply device 100 includes seventh to tenth bleeder resistors 73g to 73j. A first terminal of the seventh bleeder resistor 73g is connected to the seventh feedback wring LRg, and a second terminal of the seventh bleeder resistor 73g is connected to the ground. As in the case of the seventh bleeder resistor 73g, first terminals of the eighth to tenth bleeder resistors 73h to 73j are connected to the corresponding eighth to tenth feedback wrings LRh to LRj, and second terminals of the eighth to tenth bleeder resistors 73h to 73j are connected to the ground. It is noted that the first terminals of the seventh to tenth bleeder resistors 73g to 73j are connected to the cathodes of the corresponding feedback diodes 71g to 71j.

When the control switch 51 is turned on, current flow to the seventh feedback winding 63g is restricted by the seventh feedback diode 71g, whereby magnetic energy is stored in the seventh transformer 60g. It is noted that, as in the case of the seventh feedback winding 63g, current flow to the seventh output winding 62g is restricted by the seventh output diode 64g. In addition, as in the case of the seventh transformer 60g, when the control switch 51 is turned on, magnetic energy is stored in the eighth to tenth transformers 60h to 60j.

In contrast, when the control switch 51 is turned off, induced voltage is generated in the seventh feedback winding 63g so that an electrical potential of the third terminal T3 becomes higher than that of the fourth terminal T4g of the seventh transformer 60g. Hence, current flows though the seventh feedback winding 63g. In addition, as in the case of the seventh feedback winding 63g, current flows through the seventh output winding 62g, whereby electrical power is supplied to the boosting lower arm drive circuit DCL.

As in the case of the seventh transformer 60g, when the control switch 51 is turned off, current flows through the eighth to tenth feedback windings 63h to 63j. In addition, current flows through the eighth to tenth output windings 62h to 62j, whereby electrical power is supplied to the corresponding lower arm drive circuits DUL to DWL of the respective phases.

### Second Embodiment

Hereinafter, the second embodiment will be described focusing on differences from the first embodiment. In the first embodiment, when the control switch 51 is turned on or off, voltages generated in the feedback windings 63a to 63e are used. This may be modified to use voltages generated in at least two of the output windings 62a to 62e. In the present embodiment, for the on/off control of the control switch 51, voltages generated in the output windings 62a to 62e are used. In the present embodiment, each of the output windings 62a to 62e corresponds to a control wiring.

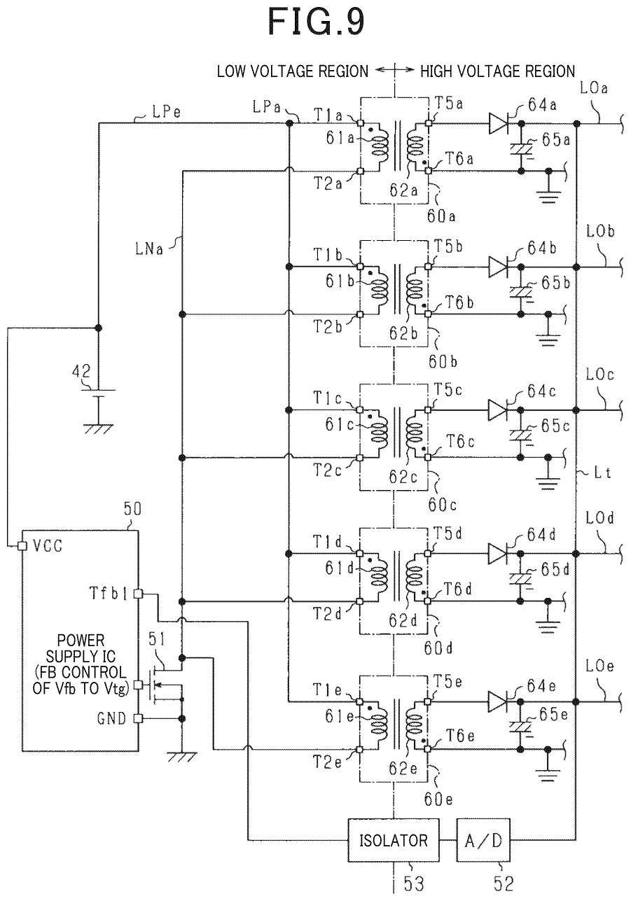

Hereinafter, with reference to FIG. 9, a configuration of the isolated power supply device 100 will be described. In the present embodiment, the transformers 60a to 60e have the corresponding input windings 61a to 61e and output windings 62a to 62e and have no feedback windings. It is noted that, in FIG. 9, the same component as that illustrated in FIG. 2 is denoted by the same reference sign for the sake of convenience. In FIG. 9, the drive circuits DCH, DCL, DUH to DWL are not shown.

Herein, configurations of output sides of the transformers 60a to 60e will be described in detail. The transformers 60a to 60e are provided with fifth terminals T5a to T5e and sixth terminals T6a to T6e. The fifth terminal T5a of the first transformer 60a is connected to the sixth terminal T6a of the first transformer 60a via the first output winding 62a. The fifth terminal T5b of the second transformer 60b is connected to the sixth terminal T6b of the second transformer 60b via the second output winding 60b. The fifth terminal T5c of the third transformer 60c is connected to the sixth terminal T6c of the third transformer 60c via the third output winding 62c. The fifth terminal T5d of the fourth transformer 60d is connected to the sixth terminal T6d of the fourth transformer 60d via the fourth output winding 62d. The fifth terminal T5e of the fifth transformer 60e is connected to the sixth terminal T6e of the first transformer 60e via the fifth output winding 62e.

The fifth terminal T5a of the first transformer 60a is connected to an output side common wiring Lt and the boosting upper arm drive circuit DCH via a first output wiring Loa. The fifth terminal T5b of the second transformer 60b is connected to the output side common wiring Lt and the U-phase upper arm drive circuit DUH via a second output wiring Lob. The fifth terminal T5c of the third transformer 60c is connected to the output side common wiring Lt and the V-phase upper arm drive circuit DVH via a third output wiring Loc. The fifth terminal T5b of the fourth transformer 60d is connected to the output side common wiring Lt and the W-phase upper arm drive circuit DWH via a fourth output wiring Lod. The fifth terminal T5e of the fifth transformer 60e is connected to the output side common wiring Lt and the lower arm drive circuits DCL, DUL, DVL, DWL via a fifth output wiring Loe. The sixth terminals T6a to Toe of the transformers 60a to 60e are connected to the ground. In the present embodiment, each of the output wirings LOa to LOe corresponds to a control wiring.

The first output wiring Loa is provided with the first output diode 64a. The anode of the first output diode 64a is connected to the fifth terminal T5a of the first transformer 60a. The cathode of the first output diode 64a is connected to the boosting upper arm drive circuit DCH and the output side common wiring Lt. The second output wiring Lob is provided with the second output diode 64b. The anode of the second output diode 64b is connected to the fifth terminal T5b of the second transformer 60b. The cathode of the second output diode 64b is connected to the U-phase upper arm drive circuit DUH and the output side common wiring Lt. The third output wiring Loc is provided with the third output diode 64c. The anode of the third output diode 64c is connected to the fifth terminal T5c of the third transformer 60c. The cathode of the third output diode 64c is connected to the V-phase upper arm drive circuit DVH and the output side common wiring Lt. It is noted that, in the present embodiment, the output side common wiring Lt is provided in the high voltage region.

The fourth output wiring Lod is provided with the fourth output diode 64d. The anode of the fourth output diode 64d is connected to the fifth terminal T5d of the fourth transformer 60d. The cathode of the fourth output diode 64d is connected to the W-phase upper arm drive circuit DWH and the output side common wiring Lt. The fifth output wiring Loe is provided with the fifth output diode 64e. The anode of the fifth output diode 64e is connected to the fifth terminal T5e of the fifth transformer 60e. The cathode of the fifth output diode 64e is connected to the lower arm drive circuits DCL, DUL, DVL, DWL and the output side common wiring Lt. In the present embodiment, each of the output diodes 64a to 64e corresponds to a control diode.

The first to fifth output capacitors 65a to 65e described above connect the cathodes of the corresponding output diodes 64a to 64e and the ground. In the present embodiment, the first to fifth output capacitors 65a to 65e correspond to control capacitors.

The isolated power supply device 100 includes an isolating and transmitting unit that transmits voltage values of the output side common wiring Lt to the power supply IC 50 while electrically isolating the output side common wiring Lt and the power supply IC 50 from each other. In the present embodiment, the isolated power supply device 100 includes, as the isolating and transmitting unit, an A/D converter 52 and an isolator 53. The A/D converter 52 is provided in the high voltage region and converts the voltage values of the output side common wiring Lt, which is an analog signal, to a digital signal. The converted digital signal is output to the isolator 53. The isolator 53 is disposed in the low voltage region and the high voltage region across the boundary between the low voltage region and the high voltage region. The isolator 53 is, for example, a digital isolator that transmits signals by using a pair of magnetic coils. The isolator 53 transmits output values of the A/D converter 52 to the power supply IC 50 while electrically isolating the output side common wiring Lt and the power supply IC 50 from each other. It is noted that the isolating and transmitting unit may be, instead of the A/D converter 52 and isolator 53, a photocoupler.

The power supply IC 50 sets a time ratio (duty ratio) of the control switch 51 based on voltage values of the output side common wiring Lt transmitted through the A/D converter 52 and the isolator 53. Hence, voltages generated in the output windings 62a to 62e are used for on/off control of the control switch 51.

According to the present embodiment described above in detail, the following effects can be obtained.

In the present embodiment, a closed circuit including the output windings 62a to 62e, the output wirings LOa to LOe, and the output side common wiring Lt is formed. In this case, when current flows through the formed closed circuit, between the transformers 60a to 60e, magnetic energy is transferred from the transformer having high magnetic energy to the transformer having low magnetic energy. Hence, due to variation in the magnitudes of loads of the drive circuits DCH, DCL, DUH to DWL, voltages generated in the output windings 62a to 62e can be suppressed from varying.

In addition, for on/off control of the control switch 51, voltages generated in the output windings 62a to 62e are used. Hence, compared with the case in which a time ratio of the control switch 51 is set based a voltage generated in any one of the output windings 62a to 62e, voltages generated in a number of output windings are used for setting the time ratio of the control switch 51. Hence, while variation in output voltages of the transformers 60a to 60e are reduced, the number of transformers not to be controlled out of the transformers 60a to 60 can be decreased. As a result, controllability of the output voltages of the transformers 60a to 60e can be increased.

It can be considered that feedback windings are provided in the low voltage region and on/off control of the control switch 51 is performed based on voltages generated in the feedback windings. However, in this case, at least two of the transformers 60a to 60e are required to be provided with additional feedback windings.

In this regard, in the present embodiment, the fifth terminals T5a to T5e of the transformers 60a to 60e are connected to the output side common wiring Lt via the corresponding output wirings LOa to LOe. Then, voltage values of the output side common wiring Lt are transmitted to the power supply IC 50 through the A/D converter 52 and the isolator 53. Hence, since additional feedback windings are not required to be provided, the number of components of the isolated power supply device 100 can be suppressed from increasing. In addition to this, according to the present embodiment, controllability of the output voltages of the transformers 60a to 60e described above can be increased. That is, while the number of components of the isolated power supply device 100 is suppressed from increasing, controllability of the output voltages of the transformers 60a to 60e can be increased.

Corresponding to the output windings 62a to 62e, the output diodes 64a to 64e and the output capacitors 65a to 65e are provided. Currents output from the fifth terminals T5a to T5e of the transformers 60a to 60e are rectified by the corresponding output diodes 64a to 64e, and the corresponding output capacitors 65a to 65e are charged. In this case, in the closed circuit including the output windings 62a to 62e, the output wirings LOa to LOe, and the output side common wiring Lt, charges stored in the output capacitors 65a to 65e are transferred, whereby current flows. Hence, magnetic energy stored in the transformers 60a to 60e is transferred. Thus, while preventing current from flowing through the closed circuit due to the inductance components of the output windings 62a to 62e is suppressed, the magnetic energy can be appropriately transferred between the transformers 60a to 60e.

### Modification of Second Embodiment

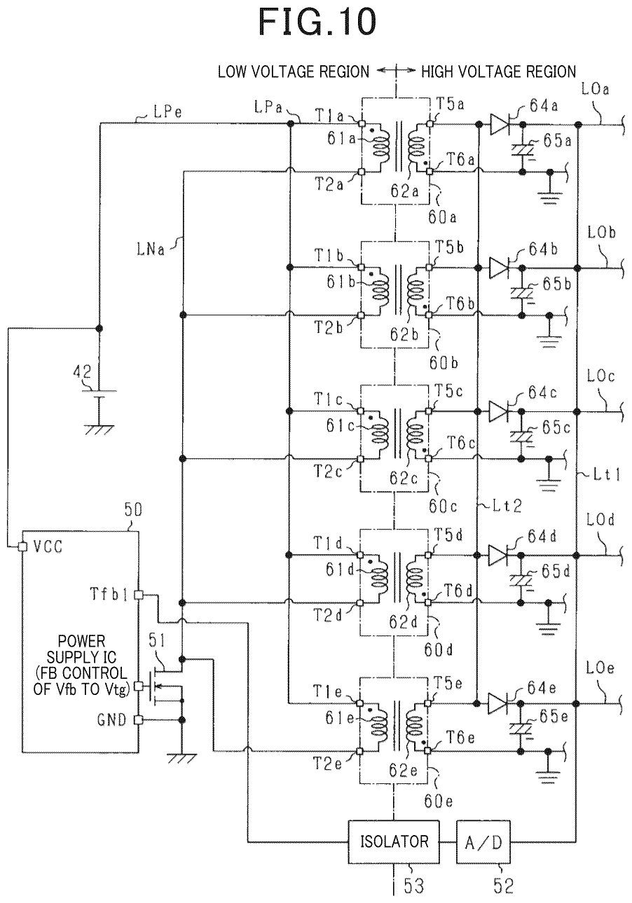

The configuration of the common wiring connecting the output windings 62a to 62e may be modified. For example, as illustrated in FIG. 10, the isolated power supply device 100 may be provided with a third common wiring Lt1 and a fourth common wiring Lt2. The third common wiring Lt1 corresponds to the output side common wiring Lt in FIG. 9. The fourth common wiring Lt2 connects the output wirings LOa to Loe. Herein, the fifth terminals T5a to T5e of the transformers 60a to 60e are connected via the fourth common wiring Lt2. In addition, the anodes of the output diodes 64a to 64e are connected to the fourth common wiring Lt2. It is noted that, in FIG. 10, the same component as that illustrated in FIG. 9 is denoted by the same reference sign for the sake of convenience.

There is a concern that when the path of a third closed circuit including the output windings 62a to 62e, the output wirings LOa to LOe, and the third common wiring Lt1 is lengthened, the amount of a voltage drop in the third closed circuit increases, whereby current flow through the third closed circuit is suppressed. In this regard, according to the present embodiment, the fifth terminals T5a to T5e of the transformers 60a to 60e are connected via the fourth common wiring Lt2. Hence, a fourth closed circuit including the output windings 62a to 62e and the fourth common wiring Lt2 is formed. In this case, the path of the fourth closed circuit through which current flows is suppressed from being longer than the path of the third closed circuit through which current flows. Thus, while the amount of a voltage drop 25 in the fourth closed circuit is suppressed from increasing, magnetic energy stored in the transformers 60a to 60e can be transferred.

Instead of using voltages generated in the output windings 62a to 62e for on/off control of the control switch 51, voltages generated in at least two of the output windings 62a to 62e may be used.

### Other Embodiments

It is noted that the above embodiments may be modified as below.

The motor control system illustrated in FIG. 1 may not include the boost converter 30. In this case, the positive electrode side bus 13 is connected to the positive electrode terminal of the high-voltage battery instead of the collector of the upper arm boost switch SCH and the first terminal of the smoothing capacitor 31.

The isolated power supply device 100 may be applied to not only the inverter 12 and the boost converter 30 but also other power conversion circuits, for example, a half-bridge circuit and a full-bridge circuit.

Output voltages of the transformers 60a to 60f may be supplied to not only the drive circuits DCH, DCL, DUH to DWL but also common electrical loads. Specific examples of the electrical loads include a seat heater, a heater for a defroster of a rear window, headlights, windshield wipers, and a blower fan of an air conditioner.

The isolated power supply device may be installed in, instead of an electric vehicle, a hybrid vehicle including a motor generator and an engine serving as in-vehicle traction units. In this case, the motor control system may be not only a one-motor control system but also a two-motor control system. Specifically, the motor control system includes a set of a first motor generator and a first inverter and a set of a second motor generator and a second inverter. The first motor generator and the second motor generator are coupled with drive wheels and the engine serving as an in-vehicle traction unit via a power dividing mechanism. The first motor generator is connected to the first inverter and serves as a starter that applies initial torque to a crankshaft of the engine, a generator that supplies electrical power to in-vehicle devices, and the like. In contrast, the second motor generator is connected to the second inverter and serves as an in-vehicle traction unit and the like. The isolated power supply device supplies electrical power to a drive circuit of switches configuring the first inverter and a drive circuit of switches configuring the second inverter.

The isolated power supply device 100 may be installed in not only a vehicle but also, for example, an aircraft, or a boat. In addition, the isolated power supply device 100 may be installed in not only movable bodies such as a vehicle, an aircraft, and a boat.

An aspect of the present disclosure provides an isolated power supply device, including:
a plurality of transformers having input windings and cores around which the input windings are wound, the input windings being connected to a DC power supply, output sides of the transformers being connected to power feeding targets corresponding to the transformers, at least two of the transformers having control windings magnetically coupled with the input windings via the cores;
a control switch that performs power feeding from the DC power supply to the input windings when being turned on and stops the power feeding from the DC power supply to the input windings when being turned off;
control wirings provided corresponding to the control windings; and
a common wiring, wherein
first terminals of the control windings are connected to the ground,
second terminals of the control windings are connected to first terminals of the corresponding control wirings,
second terminals of the control wirings are connected to the common wiring, and
the isolated power supply device further includes a control unit that turns on and off the control switch based on a voltage value of the common wiring.

Variation may occur in the magnitudes of loads of the power feeding targets. In this case, in transformers corresponding to the power feeding targets whose load has a small magnitude, supply of magnetic energy is excessive. In contrast, in transformers corresponding to the power feeding targets whose load has a large magnitude, due to insufficient supply of magnetic energy, variation is likely to occur in output voltages of the transformers. In this case, if a control switch is turned on and off based on an output voltage of any one of the transformers, there is a concern that controllability of output voltages of the other transformers decreases.

Hence, in the present disclosure, at least two of the transformers have the control windings magnetically coupled with the input windings via the cores around which the input windings are wound. First terminals of the control windings are connected to the ground. Second terminals of the control windings are connected to the common wiring via the corresponding control wirings. According to this configuration, a closed circuit including the control windings, the control wirings, and the common wiring is formed. In this case, when current flows through the closed circuit, between the transformers having the control windings, magnetic energy stored in the transformers is transferred. Specifically, magnetic energy is transferred from the transformer having high magnetic energy to the transformer having low magnetic energy. Hence, the magnetic energy stored in the transformers is suppressed from being excessive or being insufficient. Thus, variation in output voltages of the transformers can be reduced.

In addition, the control switch is turned on and off based on a voltage value of the common wiring. Hence, compared with the case in which the control switch is turned on and off based on a voltage generated in a control winding of any one of the transformers, voltages generated in a number of control windings are used for controlling the control switch. Hence, the number of transformers not to be controlled out of the transformers can be decreased.

As described above, according to the present disclosure, while variation in output voltages of the transformers is reduced, the number of transformers not to be controlled out of the transformers can be decreased. As a result, the output voltages of the transformers are suppressed from being excessively high and being excessively low. Furthermore, controllability of the output voltages of the transformers can be increased.

Hereinafter, characteristic configurations extracted from the embodiments described above will be described.

### [Configuration 1]

An isolated power supply device, including:
a plurality of transformers (60a to 60j) having input windings (61a to 61j) and cores around which the input windings are wound, the input windings being connected to a DC power supply (42), output sides of the transformers being connected to power feeding targets (DCH, DCL, DUH to DWL) corresponding to the transformers, at least two of the transformers having control windings (62a to 62e, 63a to 63j) magnetically coupled with the input windings via the cores;
a control switch (51) that performs power feeding from the DC power supply to the input windings when being turned on and stops the power feeding from the DC power supply to the input windings when being turned off;
control wirings (LRa to LRe, LRg to LRj, LOa to LOe) provided corresponding to the control windings; and
a common wiring (Ls, Ls1, Ls2, Lt, Lt1, Lt2), wherein
first terminals of the control windings are connected to the ground,
second terminals of the control windings are connected to first terminals of the corresponding control wirings,
second terminals of the control wirings are connected to the common wiring, and
the isolated power supply device further includes a control unit (50) that turns on and off the control switch based on a voltage value of the common wiring.

### [Configuration 2]

The isolated power supply device according to configuration 1, wherein
the input windings, the control windings (63a to 63j), the control switch, the control wirings (LRa to LRe, LRg to LRj), the common wiring (Ls, Ls1, Ls2), and the control unit are provided in a low voltage region electrically isolated from a high voltage region.

### [Configuration 3]

The isolated power supply device according to configuration 2, further including:
control capacitors (72a to 72e, 72g to 72j) provided corresponding to the control windings; and
control diodes (71a to 71e, 71g to 71j) provided to the control wirings, wherein
first terminals of the control capacitors are connected to the corresponding control wirings, and second terminals of the control capacitors are connected to the first terminals of the corresponding control windings, and
anodes of the control diodes are connected to the second terminals of the corresponding control windings, and cathodes of the control diodes are connected to the common wiring and the first terminals of the corresponding control capacitors.

### [Configuration 4]

The isolated power supply device according to configuration 3, further including a first voltage dividing resistor (84) and a second voltage dividing resistor (85) connected in series, wherein
a first terminal of the first voltage dividing resistor is connected to the common wiring, a second terminal of the first voltage dividing resistor is connected to a first terminal of the second voltage dividing resistor, and a second terminal of the second voltage dividing resistor is connected to the ground, and
a connection point between the first voltage dividing resistor and the second voltage dividing resistor is connected to the control unit.

### [Configuration 5]

The isolated power supply device according to configuration 3 or 4, wherein
the common wiring is a first common wiring (Ls1), and
the isolated power supply device further includes a second common wiring (Ls2) connecting the first terminals of the control wirings.

### [Configuration 6]

The isolated power supply device according to any one of configurations 2 to 5, further including bleeder resistors (73a to 73e, 73g to 73j) provided corresponding to at least one of the control windings, wherein
first terminals of the bleeder resistors are connected to the corresponding control wirings, and second terminals of the bleeder resistors are connected to the ground.

### [Configuration 7]

The isolated power supply device according to configuration 6, applied to a system including:
a power conversion circuit (12, 30) that has a plurality of series connections of the upper arm switches (SCH, SUH to SWH) and lower arm switches (SCL, SUL to SWL);
a plurality of upper arm drive circuits (DCH, DUH to DWH) that are the power feeding targets and drive the upper arm switches; and
a plurality of lower arm drive circuits (DCL, DUL to DWL) that are the power feeding targets and drive the lower arm switches, wherein
the transformers include upper arm transformers (60a to 60d) whose output sides are connected to the upper arm drive circuits and a lower arm transformer (60e) whose output side is connected to the lower arm drive circuits,
the upper arm transformers are provided individually corresponding to the upper arm drive circuits,
the lower arm transformer is a transformer common to the lower arm drive circuits,
the bleeder resistors include upper arm bleeder resistors (73a to 73d) provided corresponding to at least one of the control windings of the upper arm transformers, and a lower arm bleeder resistor (73e) provided corresponding to the control winding of the lower arm 25 transformer, and
a resistance value of the lower arm bleeder resistor is less than resistance values of the upper arm bleeder resistors.

### [Configuration 8]

The isolated power supply device according to any one of configurations 2 to 5, further including a bleeder resistor (74), wherein
a first terminal of the bleeder resistor is connected to the common wiring, and a second terminal of the bleeder resistor is connected to the ground.

### [Configuration 9]

The isolated power supply device according to configuration 1, wherein
the input windings, the control switch, and the control unit are provided in a low voltage region electrically isolated from a high voltage region,
the output sides of the transformers are provided with output winding (62a to 62e) magnetically coupled with the input windings via the core, and
the output windings and the common wiring (Lt, Lt1, Lt2) are provided in the high voltage region,
the isolated power supply device further includes:
output wirings (LOa to LOe) that correspond to the output windings and are provided in the high voltage region; and
an isolating and transmitting unit (52, 53) that is provided in the low voltage region and the high voltage region across a boundary between the low voltage region and the high voltage region, and transmits the voltage value of the common wiring to the control unit while isolating the common wiring and the control unit from each other,
first terminals of the output windings are connected to the 20) ground,
second terminals of the output windings are connected to first terminals of the corresponding output wirings,
second terminals of the output wirings are connected to the corresponding power feeding targets,
the control windings (62a to 62e) are at least two of the output windings,
the control wirings (LOa to LOe) are the output wirings corresponding to the control windings, and
the common wiring connects the second terminals of the control wirings and outputs the voltage value to the isolating and transmitting unit.

### [Configuration 10]

The isolated power supply device according to configuration 9, further including:
control capacitors (65a to 65e) provided corresponding to the control windings; and
control diodes (64a to 64e) provided to the control windings, wherein
first terminals of the control capacitors are connected to the corresponding control windings, and second terminals of the control capacitors are connected to the corresponding first terminals of the control windings, and
anodes of the control diodes are connected to the second terminals of the corresponding control windings, and cathodes of the control diodes are connected to the common wiring and the first terminals of the corresponding control capacitors.

### [Configuration 11]

The isolated power supply device according to configuration 10, wherein
the common wiring is a first common wiring (Lt1), and
the isolated power supply device further includes a second common wiring (Lt2) connecting the first terminals of the control wirings.

The present disclosure has so far been described based on embodiments. However, the present disclosure should not be construed as being limited to these embodiments or the structures. The present disclosure should encompass various modifications, and modifications within the range of equivalence. In addition, various combinations and modes, as well as other combinations and modes, including those which include one or more additional elements, or those which include fewer elements should be construed as being within the scope and spirit of the present disclosure.

What is claimed is:

1. An isolated power supply device, comprising:
a plurality of transformers having input windings and cores around which the input windings are wound, the input windings being connected to a DC power supply, output sides of the transformers being connected to power feeding targets corresponding to the transformers, at least two of the transformers having control windings magnetically coupled with the input windings via the cores;
a control switch that performs power feeding from the DC power supply to the input windings when being turned on and stops the power feeding from the DC power supply to the input windings when being turned off;
control wirings provided corresponding to the control windings; and
a common wiring, wherein
first terminals of the control windings are connected to the ground,
second terminals of the control windings are connected to first terminals of the corresponding control wirings,
second terminals of the control wirings are connected to the common wiring, and
the isolated power supply device further comprises a control unit that turns on and off the control switch based on a voltage value of the common wiring.

2. The isolated power supply device according to claim 1, wherein
the input windings, the control windings, the control switch, the control wirings, the common wiring, and the control unit are provided in a low voltage region electrically isolated from a high voltage region.

3. The isolated power supply device according to claim 2, further comprising:
control capacitors provided corresponding to the control windings; and
control diodes provided to the control wirings, wherein
first terminals of the control capacitors are connected to the corresponding control wirings, and second terminals of the control capacitors are connected to the first terminals of the corresponding control windings, and
anodes of the control diodes are connected to the second terminals of the corresponding control windings, and cathodes of the control diodes are connected to the common wiring and the first terminals of the corresponding control capacitors.

4. The isolated power supply device according to claim 3, further comprising a first voltage dividing resistor and a second voltage dividing resistor connected in series, wherein
a first terminal of the first voltage dividing resistor is connected to the common wiring, a second terminal of the first voltage dividing resistor is connected to a first terminal of the second voltage dividing resistor, and a second terminal of the second voltage dividing resistor is connected to the ground, and
a connection point between the first voltage dividing resistor and the second voltage dividing resistor is connected to the control unit.

5. The isolated power supply device according to claim 3, wherein
the common wiring is a first common wiring, and
the isolated power supply device further comprises a second common wiring connecting the first terminals of the control wirings.

6. The isolated power supply device according to claim 2, further comprising bleeder resistors provided corresponding to at least one of the control windings, wherein
first terminals of the bleeder resistors are connected to the corresponding control wirings, and second terminals of the bleeder resistors are connected to the ground.

7. The isolated power supply device according to claim 6, applied to a system including:
a power conversion circuit that has a plurality of series connections of the upper arm switches and lower arm switches;
a plurality of upper arm drive circuits that are the power feeding targets and drive the upper arm switches; and
a plurality of lower arm drive circuits that are the power feeding targets and drive the lower arm switches, wherein
the transformers include upper arm transformers whose output sides are connected to the upper arm drive circuits and a lower arm transformer whose output side is connected to the lower arm drive circuits,
the upper arm transformers are provided individually corresponding to the upper arm drive circuits,
the lower arm transformer is a transformer common to the lower arm drive circuits,
the bleeder resistors include upper arm bleeder resistors provided corresponding to at least one of the control windings of the upper arm transformers, and a lower arm bleeder resistor provided corresponding to the control winding of the lower arm transformer, and
a resistance value of the lower arm bleeder resistor is less than resistance values of the upper arm bleeder resistors.

8. The isolated power supply device according to claim 2, further comprising a bleeder resistor, wherein
a first terminal of the bleeder resistor is connected to the common wiring, and a second terminal of the bleeder resistor is connected to the ground.

9. The isolated power supply device according to claim 1, wherein
the input windings, the control switch, and the control unit are provided in a low voltage region electrically isolated from a high voltage region,
the output sides of the transformers are provided with output winding magnetically coupled with the input windings via the core, and
the output windings and the common wiring are provided in the high voltage region,
the isolated power supply device further comprises:
output wirings that correspond to the output windings and are provided in the high voltage region; and
an isolating and transmitting unit that is provided in the low voltage region and the high voltage region across a boundary between the low voltage region and the high voltage region, and transmits the voltage value of the common wiring to the control unit while isolating the common wiring and the control unit from each other,
first terminals of the output windings are connected to the ground,
second terminals of the output windings are connected to first terminals of the corresponding output wirings,
second terminals of the output wirings are connected to the corresponding power feeding targets,
the control windings are at least two of the output windings,
the control wirings are the output wirings corresponding to the control windings, and
the common wiring connects the second terminals of the control wirings and outputs the voltage value to the isolating and transmitting unit.

10. The isolated power supply device according to claim 9, further comprising:
control capacitors provided corresponding to the control windings; and
control diodes provided to the control windings, wherein
first terminals of the control capacitors are connected to the corresponding control windings, and second terminals of the control capacitors are connected to the corresponding first terminals of the control windings, and
anodes of the control diodes are connected to the second terminals of the corresponding control windings, and cathodes of the control diodes are connected to the common wiring and the first terminals of the corresponding control capacitors.

11. The isolated power supply device according to claim 10, wherein
the common wiring is a first common wiring, and
the isolated power supply device further comprises a second common wiring connecting the first terminals of the control wirings.
